(19) United States
(12) Patent Application Publication
(10) Pub. No.: US 2025/0029817 A1
(43) Pub. Date: Jan. 23, 2025

(54) SUBSTRATE PROCESSING APPARATUS

(71) Applicant: JUSUNG ENGINEERING CO., LTD., Gwangju-si (KR)

(72) Inventors: WOONG KYO OH, Gwangju-si (KR); Young Woon KIM, Gwangju-si (KR); Kwang Su YOO, Gwangju-si (KR); Won Tae CHO, Gwangju-si (KR); Chul Joo HWANG, Gwangju-si (KR)

(21) Appl. No.: 18/909,926

(22) Filed: Oct. 8, 2024

Related U.S. Application Data
(62) Division of application No. 16/975,391, filed on Aug. 24, 2020.

(30) Foreign Application Priority Data
Apr. 20, 2018 (KR) 10-2018-0046356
Apr. 27, 2018 (KR) 10-2018-0048872
Apr. 19, 2019 (KR) 10-2019-0045798

(51) Int. Cl. H01J 37/32; C23C 16/458; C23C 16/509; H01L 21/67

(52) U.S. Cl. CPC H01J 37/32568; C23C 16/4584; C23C 16/509; H01J 37/3244; H01J 37/32715; H01L 21/67069; H01J 2237/332; H01J 2237/334

(57) ABSTRACT

The present invention relates to a substrate processing apparatus including: a chamber; a first electrode disposed on the chamber; a second electrode disposed under the first electrode, the second electrode including a plurality of openings; a plurality of protrusion electrodes extending from the first electrode to the plurality of openings of the second electrode; a substrate supporter being opposite to the second electrode and supporting a substrate; a first discharging region between a lower surface of the first electrode and an upper surface of the second electrode; a second discharging region between a side surface of the protrusion electrode and an opening inner surface of the second electrode; a third discharging region between a lower surface of the protrusion electrode and the opening inner surface of the second electrode; and a fourth discharging region between the second electrode and the substrate, wherein plasma is generated in at least one region of the first to fourth discharging regions.

### CROSS-REFERENCE TO RELATED APPLICATION

This U.S. non-provisional patent application is a divisional of U.S. patent application Ser. No. 16/975,391, filed on Aug. 24, 2020, Publication No. US 2021/0035780 A1, which claims priority under 35 U.S.C. § 371 to International Patent Application No. PCT/KR2019/004734, filed on Apr. 19, 2019, and to 35 U.S.C. § 119 to Korean Patent Application No. 10-2019-0045798, filed on Apr. 19, 2019, Korean Patent Application No. 10-2018-0046356, filed on Apr. 20, 2018, and Korean Patent Application No. 10-2018-0048872, filed on Apr. 27, 2018, in the Korean Intellectual Property Office, the contents of both which are herein incorporated by reference in their entireties.

### TECHNICAL FIELD

The present disclosure relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed, and examples of the processing process include a deposition process of depositing a thin film including a specific material on a substrate, a photo process of selectively exposing a portion of a thin film by using a photosensitive material, an etching process of removing the selectively exposed portion of the thin film to form a pattern, etc.

A related art substrate processing apparatus includes a supporting part which supports a substrate and an electrode unit which is disposed on the supporting part. The related art substrate processing apparatus generates plasma by using the electrode unit, and thus, performs a processing process on the substrate.

However, in the related art substrate processing apparatus, it is not considered to differentiate a region which generates the plasma by using the electrode unit and a region which does not generate the plasma, and due to this, there is a problem where the efficiency of the processing process performed on the substrate is reduced.

### DISCLOSURE

### Technical Problem

The present inventive concept is devised to solve the above-described problem and is for providing substrate processing apparatuses for increasing the efficiency of a processing process performed on a substrate.

### Technical Solution

To accomplish the above-described objects, the present inventive concept may include below-described elements.

An apparatus for processing substrate according to the present inventive concept may include: a chamber; a first electrode disposed on the chamber; a second electrode disposed under the first electrode, the second electrode including a plurality of openings; a plurality of protrusion electrodes extending from the first electrode to the plurality of openings of the second electrode; a substrate supporter being opposite to the second electrode and supporting a substrate; a first discharging region between a lower surface of the first electrode and an upper surface of the second electrode; a second discharging region between a side surface of the protrusion electrode and an opening inner surface of the second electrode; a third discharging region between a lower surface of the protrusion electrode and the opening inner surface of the second electrode; and a fourth discharging region between the second electrode and the substrate. Plasma may be generated in at least one region of the first to fourth discharging regions.

An apparatus for processing substrate according to the present inventive concept may include: a chamber; a first electrode disposed on the chamber; a second electrode disposed under the first electrode; a plurality of protrusion electrodes extending from the first electrode to a portion thereunder; a first opening provided to pass through the second electrode; a second opening provided to pass through the second electrode at a position spaced apart from the first opening; and a third opening provided to pass through the second electrode at a position spaced apart from each of the first opening and the second opening. In each of the first to third openings, an opening area of a lower surface of the second electrode may be greater than an opening area of the upper surface of the second electrode.

An apparatus for processing substrate according to the present inventive concept may include: a chamber; a first electrode disposed on the chamber; a second electrode disposed under the first electrode, the second electrode including a plurality of openings; a plurality of protrusion electrodes extending from the first electrode to the plurality of openings of the second electrode; and a substrate supporter being opposite to the second electrode and supporting a substrate. In an opening of the second electrode, an opening area of the upper surface of the second electrode may differ from an opening area of a lower surface of the second electrode.

### Advantageous Effect

According to the present inventive concept, the following effects can be obtained. The present inventive concept may be implemented so that plasma is not generated in a region requiring no plasma, based on a process condition, and thus, may decrease the amount of lost radical caused by the occurrence of the plasma in the region requiring no plasma and may reduce a pollution occurrence rate caused by performing of undesired deposition in the region requiring no plasma.

The present inventive concept may be implemented so that plasma is generated in only a region requiring the plasma, based on a process condition, and thus, may increase a plasma density and decomposition efficiency in the region requiring the plasma.

### DESCRIPTION OF DRAWINGS

FIG. 1 is a schematic side cross-sectional view of a substrate processing apparatus according to the present inventive concept.

FIGS. 2 to 10 are side cross-sectional views illustrating an enlarged portion A of FIG. 1 in a substrate processing apparatus according to the present inventive concept.

FIG. 11 is a side cross-sectional view illustrating an enlarged portion B of FIG. 1 in a substrate processing apparatus according to the present inventive concept.

FIG. 12 is a schematic bottom view illustrating a lower surface of a first electrode in a substrate processing apparatus according to the present inventive concept.

FIG. 13 is a side cross-sectional view illustrating an embodiment where third distances to a protrusion electrode differ in a substrate processing apparatus according to the present inventive concept.

FIGS. 14 and 15 are side cross-sectional views illustrating an enlarged portion A of FIG. 1 for describing a first gas distribution hole in a substrate processing apparatus according to the present inventive concept.

FIGS. 16 and 17 are side cross-sectional views illustrating an enlarged portion A of FIG. 1 for describing a second gas distribution hole in a substrate processing apparatus according to the present inventive concept.

FIG. 18 is a side cross-sectional view illustrating an opening according to a first embodiment in an enlarged portion A of FIG. 1 in a substrate processing apparatus according to a modified embodiment of the present inventive concept.

FIG. 19 is a side cross-sectional view illustrating an opening according to a second embodiment in an enlarged portion A of FIG. 1 in a substrate processing apparatus according to a modified embodiment of the present inventive concept.

FIG. 20 is a side cross-sectional view illustrating an opening according to a third embodiment in an enlarged portion A of FIG. 1 in a substrate processing apparatus according to a modified embodiment of the present inventive concept.

FIG. 21 is a schematic bottom view illustrating a lower surface of a second electrode in a substrate processing apparatus according to a modified embodiment of the present inventive concept.

FIG. 22 is a side cross-sectional view illustrating modified embodiments of an opening according to a second embodiment in a substrate processing apparatus according to a modified embodiment of the present inventive concept.

FIG. 23 is a side cross-sectional view illustrating an opening according to a fourth embodiment in an enlarged portion A of FIG. 1 in a substrate processing apparatus according to a modified embodiment of the present inventive concept.

FIG. 24 is a side cross-sectional view illustrating modified embodiments of an opening according to a fourth embodiment in a substrate processing apparatus according to a modified embodiment of the present inventive concept.

FIG. 25 is a side cross-sectional view illustrating a first opening in an enlarged portion A of FIG. 1 in a substrate processing apparatus according to a modified embodiment of the present inventive concept.

FIG. 26 is a side cross-sectional view illustrating a second opening in an enlarged portion A of FIG. 1 in a substrate processing apparatus according to a modified embodiment of the present inventive concept.

FIG. 27 is a side cross-sectional view illustrating a third opening in an enlarged portion A of FIG. 1 in a substrate processing apparatus according to a modified embodiment of the present inventive concept.

FIG. 28 is a schematic bottom view illustrating an embodiment where a lower surface of a second electrode is divided into three regions and a processing process is performed in a substrate processing apparatus according to a modified embodiment of the present inventive concept.

FIG. 29 is a side cross-sectional view illustrating a modified embodiment of a first opening in an enlarged portion A of FIG. 1 in a substrate processing apparatus according to a modified embodiment of the present inventive concept.

### DETAILED DESCRIPTION

Hereinafter, an embodiment of a substrate processing apparatus according to the present inventive concept will be described in detail with reference to the accompanying drawings.

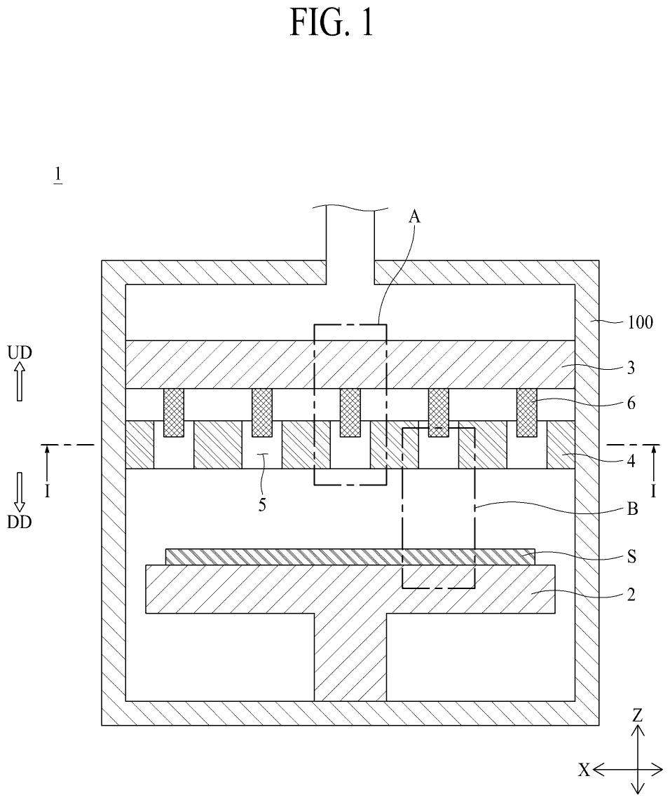

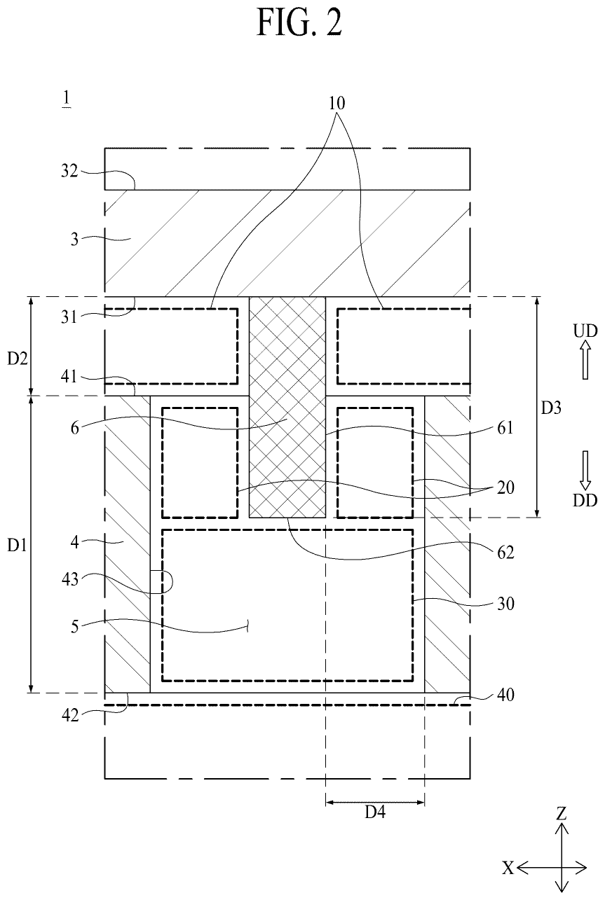

Referring to FIGS. 1 and 2, a substrate processing apparatus 1 according to the present inventive concept performs a processing process on a substrate S. For example, the substrate processing apparatus 1 according to the present inventive concept may perform at least one of a deposition process of depositing a thin film on the substrate S and an etching process of removing a portion of the thin film deposited on the substrate S. For example, the substrate processing apparatus 1 according to the present inventive concept may perform a deposition process such as a chemical vapor deposition (CVD) process or an atomic layer deposition (ALD) process. The substrate processing apparatus 1 according to the present inventive concept includes a substrate supporter 2, a first electrode 3, a second electrode 4, an opening 5, and a protrusion electrode 6.

Referring to FIG. 1, the substrate supporter 2 supports the substrate S. The substrate supporter 2 may be disposed to be opposite to the second electrode 4. The substrate S may be supported by the substrate supporter 2. When the substrate supporter 2 is disposed under the second electrode 4, the substrate S may be supported by an upper surface of the substrate supporter 2. Therefore, the substrate S may be supported by the substrate supporter 2 so as to be disposed between the substrate supporter 2 and the second electrode 4 with respect to a vertical direction (a Z-axis direction). The substrate S may be a semiconductor substrate, a wafer, or the like. The substrate supporter 2 may support a plurality of substrates S. The substrate supporter 2 may be coupled to a chamber 100 which provides a processing space where the processing process is performed. The substrate supporter 2 may be disposed inside the chamber 100. The substrate supporter 2 may be rotatably coupled to the chamber 100. In this case, the substrate supporter 2 may be connected to a rotational unit which provides a rotational force. The rotational unit may rotate the substrate supporter 2 to rotate the substrate S supported by the substrate supporter 2.

Referring to FIGS. 1 and 2, the first electrode 3 is disposed in an upper portion the chamber 100. The first electrode 3 may be disposed to be located on the second electrode 4 in the upper portion of the chamber 100. The first electrode 3 may be disposed apart from the second electrode 4 by a certain distance in an upward direction UD (an arrow direction). The first electrode 3 may be coupled to the chamber 100 so as to be disposed in the chamber 100. The first electrode 3 may be used to generate plasma. The first electrode 3 may be provided in a wholly tetragonal plate shape, but is not limited thereto and may be provided in another shape such as a circular plate shape which enables the plasma to be generated.

Referring to FIGS. 1 and 2, the second electrode 4 is disposed in a lower portion of the first electrode 3. The second electrode 4 may be disposed on the substrate supporter 2. The second electrode 4 may be disposed apart from the substrate supporter 2 by a certain distance in the upward direction UD (the arrow direction). The second electrode 4 may be coupled to the chamber 100 so as to be disposed in the chamber 100. The second electrode 4 may be used to generate the plasma. The second electrode 4 may be provided in a wholly tetragonal plate shape, but is not limited thereto and may be provided in another shape such as a circular plate shape which enables the plasma to be generated.

When the second electrode 4 is disposed under the first electrode 3, the second electrode 4 may be disposed so that an upper surface 41 thereof faces the first electrode 3 and a lower surface 42 thereof faces the substrate supporter 2. In this case, the first electrode 3 may be disposed in order for a lower surface 31 thereof to face the upper surface 41 of the second electrode 4. The lower surface 31 of the first electrode 3 and the upper surface 41 of the second electrode 4 may be disposed apart from each other by a certain distance with respect to the vertical direction (the Z-axis direction).

A radio frequency (RF) power may be applied to one of the second electrode 4 and the first electrode 3, and the other electrode may be grounded. Therefore, plasma may be generated through discharging caused by an electric field between the second electrode 4 and the first electrode 3. The RF power may be applied to the second electrode 4, and the first electrode 3 may be grounded. The second electrode 4 may be grounded, and the RF power may be applied to the first electrode 3.

Referring to FIGS. 1 and 2, the opening 5 may be provided to pass through the second electrode 4. The opening 5 may be provided to pass through the upper surface 41 of the second electrode 4 and the lower surface 42 of the second electrode 4. The opening 5 may be provided in a wholly cylindrical shape, but is not limited thereto and may be provided in another shape such as a rectangular parallelepiped shape. The opening 5 may be provided in plurality in the second electrode 4. In this case, the openings 5 may be disposed at positions space apart from one another.

Referring to FIGS. 1 and 2, the protrusion electrode 6 extends from the first electrode 3 and extends to the opening 5 provided in the second electrode 4. The protrusion electrode 6 may protrude from the first electrode 3 in a downward direction DD (an arrow direction). In this case, the protrusion electrode 6 may protrude from a portion, located on the opening 5, of the lower surface 31 of the first electrode 3. That is, the protrusion electrode 6 may be disposed at a position corresponding to the opening 5. The protrusion electrode 6 may be coupled to the lower surface 31 of the first electrode 3. The protrusion electrode 6 and the first electrode 3 may be provided as one body. When the first electrode 3 is grounded, the protrusion electrode 6 may be grounded through the first electrode 3. When the RF power is applied to the first electrode 3, the RF power may be applied to the protrusion electrode 6 through the first electrode 3.

The substrate processing apparatus 1 according to the present inventive concept may include a plurality of protrusion electrodes 6. In this case, the second electrode 4 may include the plurality of openings 5. The protrusion electrodes 6 may be disposed at positions spaced apart from one another. The protrusion electrodes 6 may protrude portions, located on the openings 5, of the lower surface 31 of the first electrode 3. That is, the protrusion electrodes 6 may be disposed at positions respectively corresponding to the openings 5.

Here, the substrate processing apparatus 1 according to the present inventive concept may include a first discharging region 10, a second discharging region 20, a third discharging region 30, and a fourth discharging region 40.

The first discharging region 10 may be disposed between the lower surface 31 of the first electrode 3 and the upper surface 41 of the second electrode 4. With respect to the vertical direction (the Z-axis direction), the first discharging region 10 may be disposed between the first electrode 3 and the second electrode 4.

The second discharging region 20 may be disposed between a side surface 61 of the protrusion electrode 6 and an opening inner surface 43 of the second electrode 4. The opening 5 is provided to pass through the second electrode 4, and thus, the opening inner surface 43 is a surface provided in an inner side of the second electrode 4. A portion, inserted into the opening 5, of the protrusion electrode 6 may be disposed in an inner side of the second discharging region 20. That is, the second discharging region 20 may be disposed to surround the portion, inserted into the opening 5, of the protrusion electrode 6. With respect to the vertical direction (the Z-axis direction), the second discharging region 20 may be disposed under the first discharging region 10.

The third discharging region 30 may be disposed between a lower surface 62 of the protrusion electrode 6 and the opening inner surface 43. With respect to the vertical direction (the Z-axis direction), the third discharging region 30 may be disposed between a lower side of the second discharging region 20 and a lower side of the protrusion electrode 6.

The fourth discharging region 40 may be disposed between the second electrode 4 and the substrate S. With respect to the vertical direction (the Z-axis direction), the fourth discharging region 40 may be disposed between the lower surface 42 of the second electrode 4 and the substrate supporter 2.

The substrate processing apparatus 1 according to the present inventive concept may generate plasma in at least one region of the first to fourth discharging regions 10 to 40. The substrate processing apparatus 1 according to the present inventive concept may generate the plasma in only one region of the first to fourth discharging regions 10 to 40, or may generate the plasma in two or more regions of the first to fourth discharging regions 10 to 40.

Therefore, the substrate processing apparatus 1 according to the present inventive concept may be implemented to generate the plasma in only a region corresponding to the kind of the processing process performed on the substrate S, a deposition condition such as the kind, thickness, and uniformity of a thin film layer which is deposited on the substrate S when performing the deposition process, and a process condition such as an area of the substrate S. Accordingly, the substrate processing apparatus 1 according to the present inventive concept may obtain the following effects.

First, the substrate processing apparatus 1 according to the present inventive concept may be implemented not to generate the plasma in a region requiring no plasma, based on the process condition, and thus, may decrease the amount of lost radical caused by the occurrence of the plasma in the region requiring no plasma. Also, the substrate processing apparatus 1 according to the present inventive concept may reduce a pollution occurrence rate caused by performing of undesired deposition in the region requiring no plasma.

Second, the substrate processing apparatus 1 according to the present inventive concept may be implemented to generate the plasma in only a region requiring the plasma, based on the process condition, and thus, may increase a plasma density and decomposition efficiency in the region requiring the plasma.

Here, the substrate processing apparatus 1 according to the present inventive concept may include various embodiments in association with the first electrode 3, the second electrode 4, and the protrusion electrode 6, based on a position of a region which generates the plasma and a position of a region which does not generate the plasma.

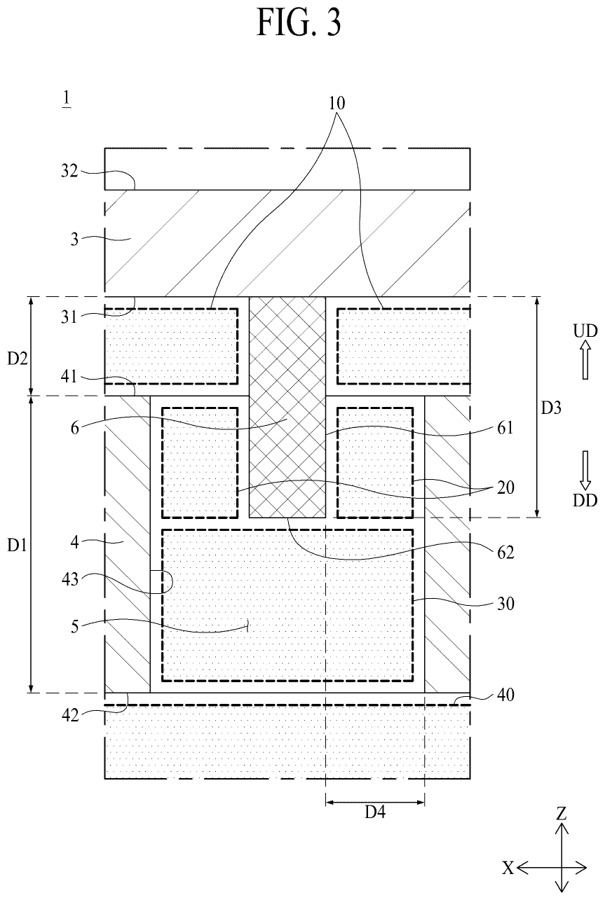

Such embodiments will be sequentially described with reference to the accompanying drawings. In FIGS. 3 to 7, a hatched portion represents a discharging region where the plasma is generated, and an unhatched portion represents a discharging region where the plasma is not generated.

First, such embodiments may be implemented to include a first distance D1, a second distance D2, a third distance D3, and a fourth distance D4 in common as illustrated in FIG. 2.

The first distance D1 corresponds to a distance between the upper surface 41 of the second electrode 4 and the lower surface 42 of the second electrode 4. With respect to the vertical direction (the Z-axis direction), the first distance D1 may correspond to a thickness of the second electrode 4.

The second distance D2 corresponds to a distance between the lower surface 31 of the first electrode 3 and the upper surface 41 of the second electrode 4. With respect to the vertical direction (the Z-axis direction), the second distance D2 may correspond to an interval by which the first electrode 3 and the second electrode 4 are spaced apart from each other.

The third distance D3 corresponds to a distance from the lower surface 31 of the first electrode 3 to the lower surface 62 of the protrusion electrode 6. With respect to the vertical direction (the Z-axis direction), the third distance D3 may correspond to a length by which the protrusion electrode 6 protrudes from the lower surface 31 of the first electrode 3 to a portion thereunder.

The fourth distance D4 corresponds to a distance between the side surface 61 of the protrusion electrode 6 and the opening inner surface 43 of the second electrode 4. With respect to the vertical direction (the Z-axis direction), the fourth distance D4 may correspond to an interval by which the protrusion electrode 6 and the second electrode 4 are spaced apart from each other.

Next, referring to FIG. 3, a first embodiment may be implemented to generate plasma in all of the first to fourth discharging regions 10 to 40. In this case, the first to fourth distances D1 to D4 may be implemented to have a size which enables the plasma to be generated in all of the first to fourth discharging regions 10 to 40. For example, each of the first to fourth distances D1 to D4 may be implemented to have a size of 3 mm or more. In the first embodiment, a plasma density and decomposition efficiency may increase in all of the first to fourth discharging regions 10 to 40. In a case where the substrate processing apparatus 1 according to the present inventive concept performs a CVD process on the substrate S, the first embodiment may enhance an effect of increasing a plasma density. In a case where the substrate processing apparatus 1 according to the present inventive concept performs an ALD process on the substrate S, the first embodiment may enhance an effect of increasing decomposition efficiency.

In the first embodiment, the first distance D1 may be implemented to be greater than the second distance D2. The third distance D3 may be implemented to be greater than the second distance D2. The third distance D3 may be implemented so that the lower surface 62 of the protrusion electrode 6 is located in the second electrode 4 through the opening 5. The fourth distance D4 may be implemented to be greater than the second distance D2.

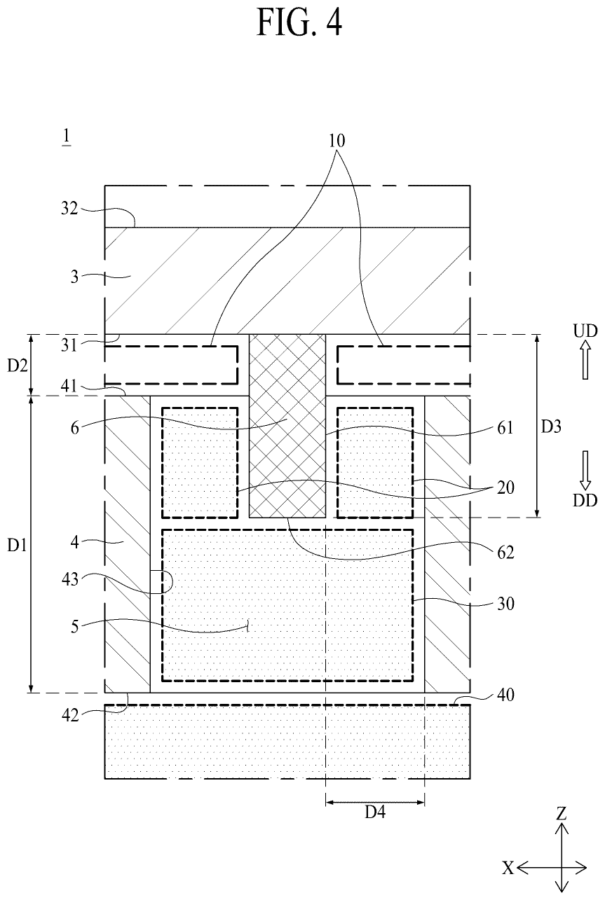

Next, referring to FIG. 4, a second embodiment may be implemented so that plasma is not generated in the first discharging region 10 and is generated in all of the second to fourth discharging regions 20 to 40. In this case, the second distance D2 may be implemented to have a size which allows the plasma not to be generated in the first discharging region 10. For example, the second distance D2 may be implemented to have a size of less than 3 mm. The first distance D1, the third distance D3, and the fourth distance D4 may be implemented to have a size which enables the plasma to be generated in all of the second to fourth discharging regions 20 to 40. For example, each of the first distance D1, the third distance D3, and the fourth distance D4 may be implemented to have a size of 3 mm or more. In the second embodiment, the amount of lost radical may decrease in the first discharging region 10, and a plasma density and decomposition efficiency may increase in all of the second to fourth discharging regions 20 to 40. In a case where the substrate processing apparatus 1 according to the present inventive concept performs a CVD process on the substrate S, the second embodiment may enhance an effect of increasing a plasma density. In a case where the substrate processing apparatus 1 according to the present inventive concept performs an ALD process on the substrate S, the second embodiment may enhance an effect of increasing decomposition efficiency.

In the second embodiment, the first distance D1 may be implemented to be greater than the second distance D2. The third distance D3 may be implemented to be greater than the second distance D2. The third distance D3 may be implemented so that the lower surface 62 of the protrusion electrode 6 is located in the second electrode 4 through the opening 5. The fourth distance D4 may be implemented to be greater than the second distance D2.

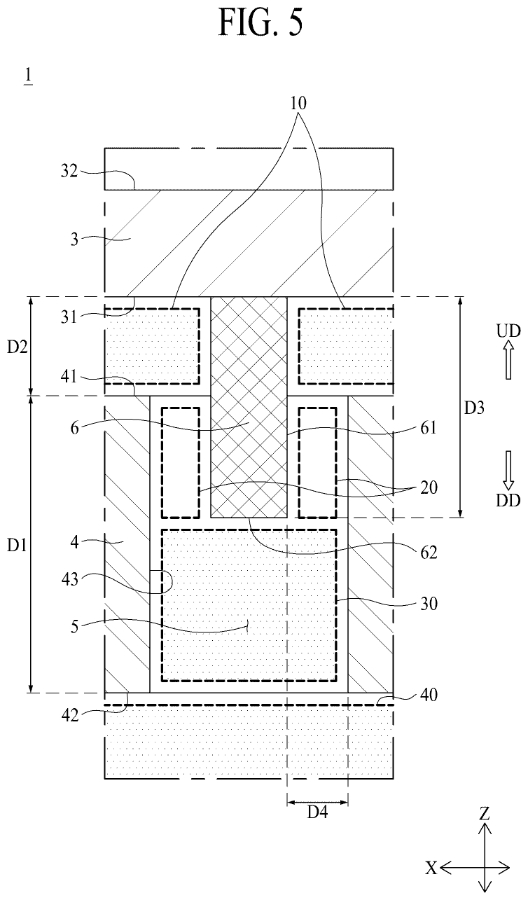

Next, referring to FIG. 5, a third embodiment may be implemented so that plasma is not generated in the second discharging region 20. Also, the third embodiment may be implemented to generate the plasma in all of the first discharging region 10, the third discharging region 30, and the fourth discharging region 40. In this case, the fourth distance D4 may be implemented to have a size which allows the plasma not to be generated in the second discharging region 20. The fourth distance D4 may be implemented to have a size which is less than that of the second distance D2. For example, the fourth distance D4 may be implemented to have a size of less than 3 mm. The first to third distances D1 to D3 may be implemented to have a size which enables the plasma to be generated in all of the first discharging region 10, the third discharging region 30, and the fourth discharging region 40. For example, each of the first to third distances D1 to D3 may be implemented to have a size of 3 mm or more. In the third embodiment, the amount of lost radical may decrease in the second discharging region 20, and a plasma density and decomposition efficiency may increase in all of the first discharging region 10, the third discharging region 30, and the fourth discharging region 40. In a case where the substrate processing apparatus 1 according to the present inventive concept performs a CVD process on the substrate S, the third embodiment may enhance an effect of increasing a plasma density. In a case where the substrate processing apparatus 1 according to the present inventive concept performs an ALD process on the substrate S, the third embodiment may enhance an effect of increasing decomposition efficiency.

In the third embodiment, the first distance D1 may be implemented to be greater than the second distance D2. The third distance D3 may be implemented to be greater than the second distance D2. The third distance D3 may be implemented so that the lower surface 62 of the protrusion electrode 6 is located in the second electrode 4 through the opening 5. The fourth distance D4 may be implemented to be less than the second distance D2.

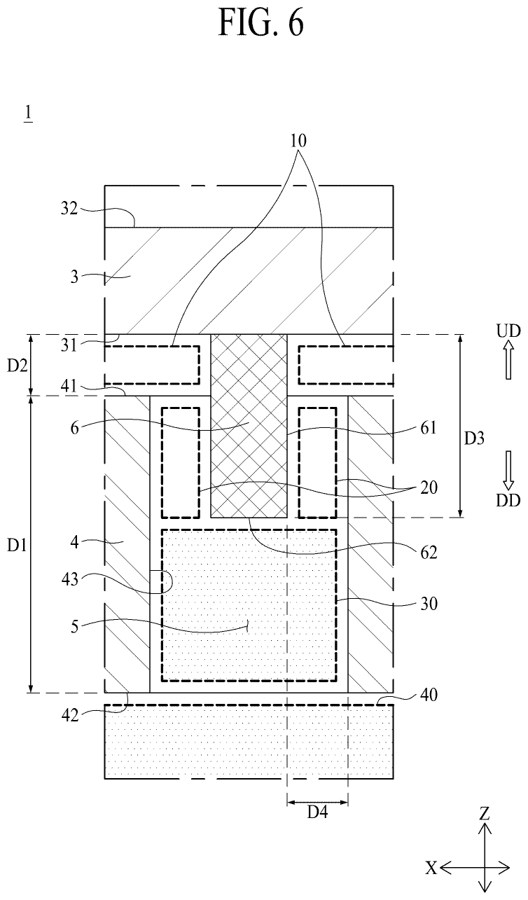

Next, referring to FIG. 6, a fourth embodiment may be implemented so that plasma is not generated in the first discharging region 10 and the second discharging region 20. Also, the fourth embodiment may be implemented to generate the plasma in all of the third discharging region 30 and the fourth discharging region 40. In this case, the second distance D2 may be implemented to have a size which allows the plasma not to be generated in the first discharging region 10. For example, the second distance D2 may be implemented to have a size of less than 3 mm. The fourth distance D4 may be implemented to have a size which allows the plasma not to be generated in the second discharging region 20. The fourth distance D4 may be implemented to have a size which is less than that of the second distance D2. For example, the fourth distance D4 may be implemented to have a size of less than 3 mm. The third distance D3 may be implemented to have a size which enables the plasma to be generated in all of the third discharging region 30 and the fourth discharging region 40. For example, the third distance D3 may be implemented to have a size of 3 mm or more. In the fourth embodiment, the amount of lost radical may decrease in the first discharging region 10 and the second discharging region 20, and a plasma density may increase in all of the third discharging region 30 and the fourth discharging region 40.

In the fourth embodiment, the first distance DI may be implemented to be greater than the second distance D2. The third distance D3 may be implemented to be greater than the second distance D2. The third distance D3 may be implemented so that the lower surface 62 of the protrusion electrode 6 is located in the second electrode 4 through the opening 5. The third distance D3 may be implemented to be equal to the second distance D2. In this case, the protrusion electrode 6 may be disposed in order for the lower surface 62 not to be inserted into the opening 5. The fourth distance D4 may be implemented to be less than the second distance D2.

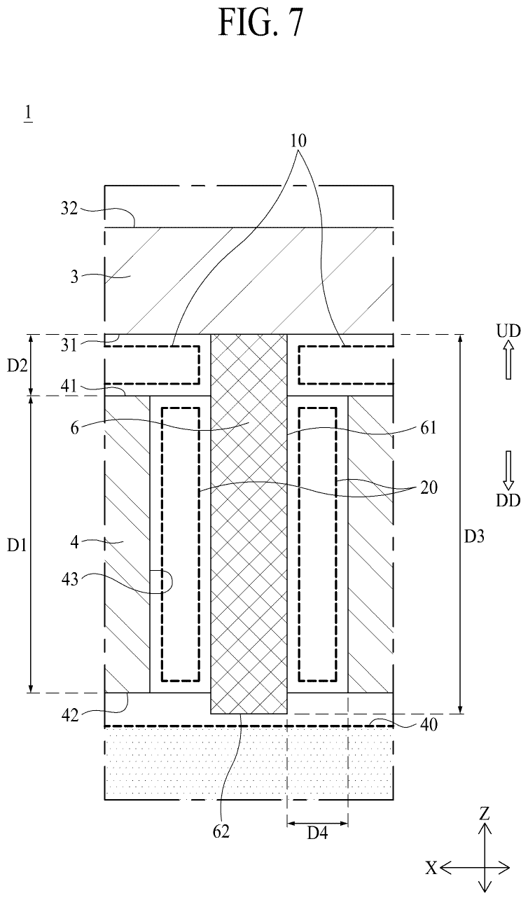

Next, referring to FIG. 7, a fifth embodiment may be implemented so that plasma is not generated in the first to third discharging regions 10 to 30. Also, the fifth embodiment may be implemented to generate the plasma in the fourth discharging region 40. In this case, the second distance D2 may be implemented to have a size which allows the plasma not to be generated in the first discharging region 10. For example, the second distance D2 may be implemented to have a size of less than 3 mm. The fourth distance D4 may be implemented to have a size which allows the plasma not to be generated in the second discharging region 20. The fourth distance D4 may be implemented to have a size which is less than that of the second distance D2. For example, the fourth distance D4 may be implemented to have a size of less than 3 mm. The third distance D3 may be implemented to have a size which allows the plasma not to be generated in the third discharging region 30. The third distance D3 may be implemented to have a size which is greater than a sum of the first distance D1 and the second distance D2. For example, a height of the third discharging region 30 may be implemented to be less than 3 mm with respect to the vertical direction (the Z-axis direction). The fifth embodiment may generate plasma having a density suitable for forming a film requiring porosity.

In the fifth embodiment, the first distance D1 may be implemented to be greater than the second distance D2. The third distance D3 may be implemented to be greater than a sum of the first distance DI and the second distance D2. In this case, the protrusion electrode 6 may be disposed at a position which is spaced apart from the lower surface 42 of the second electrode 4 in a direction toward a lower portion. That is, the protrusion electrode 6 may be disposed to protrude to a portion under the second electrode 4. The third distance D3 may be implemented to be equal to the sum of the first distance D1 and the second distance D2. In this case, the lower surface 62 of the protrusion electrode 6 and the lower surface 42 of the second electrode 4 may be disposed at the same position with respect to the vertical direction (the Z-axis direction). The fourth distance D4 may be implemented to be less than the second distance D2.

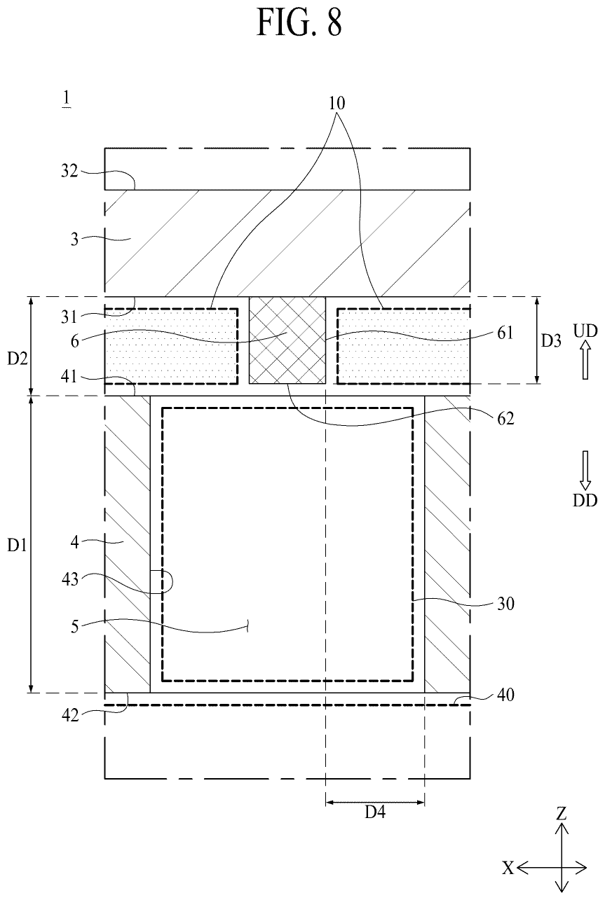

Next, referring to FIG. 8, a sixth embodiment may be implemented to generate plasma in only the first discharging region 10. Also, the sixth embodiment may be implemented in order for the plasma not to be generated in the second to fourth discharging regions 20 to 40. In this case, the third distance D3 may be implemented to have a size which is less than the second distance D2. Therefore, a length of the protrusion electrode 6 protruding from the lower surface 31 of the first electrode 3 may be implemented to be shorter than an interval by which the lower surface 31 of the first electrode 3 is spaced apart from the upper surface 41 of the second electrode 4. In this case, the protrusion electrode 6 may be disposed so that the protrusion electrode 6 is not inserted into the opening 5 and the lower surface 62 thereof is spaced apart from the opening 5 in an upward direction UD (an arrow direction). In the sixth embodiment, the plasma may increase a distance spaced apart from the substrate S, thereby decreasing a risk where the substrate S and a thin film formed on the substrate S is damaged by the plasma. In the sixth embodiment, the third distance D3 may be 0.7 or more times the second distance D2 and may be less than the second distance D2. In the sixth embodiment, the second discharging region 20 (illustrated in FIG. 5) may be omitted.

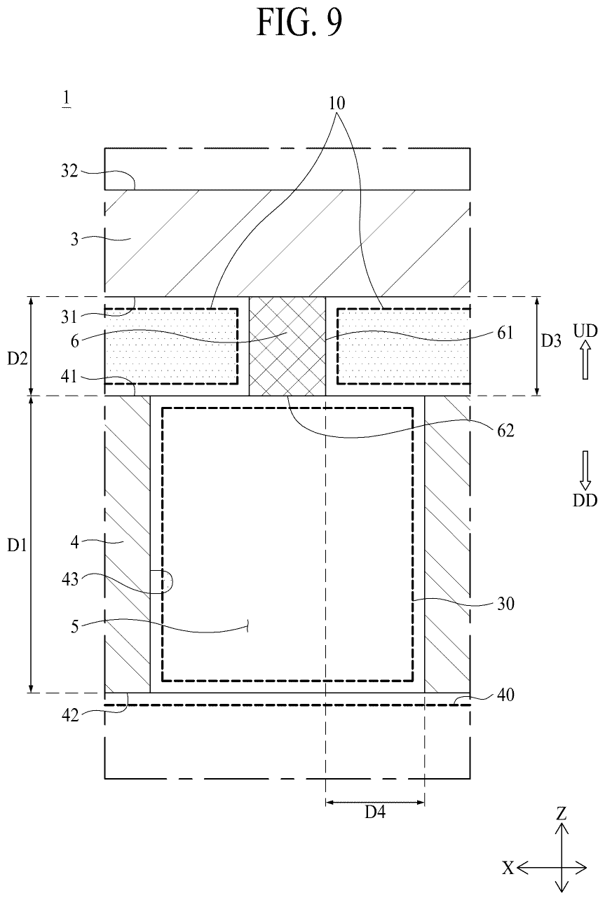

Next, referring to FIG. 9, a seventh embodiment may be implemented to generate plasma in only the first discharging region 10. Also, the seventh embodiment may be implemented in order for the plasma not to be generated in the second to fourth discharging regions 20 to 40. In this case, the third distance D3 and the second distance D2 may be implemented to have the same size. Therefore, a length of the protrusion electrode 6 protruding from the lower surface 31 of the first electrode 3 and an interval by which the lower surface 31 of the first electrode 3 is spaced apart from the upper surface 41 of the second electrode 4 may be implemented to be equal. In this case, the protrusion electrode 6 may be disposed so that the protrusion electrode 6 is not inserted into the opening 5 and the lower surface 62 thereof contacts an upper surface of the opening 5. The seventh embodiment may decrease a risk where the substrate S and the thin film formed on the substrate S is damaged by the plasma, and moreover, may more increase decomposition efficiency and a density of plasma generated in the first discharging region 10. In the seventh embodiment, the second discharging region 20 (illustrated in FIG. 5) may be omitted.

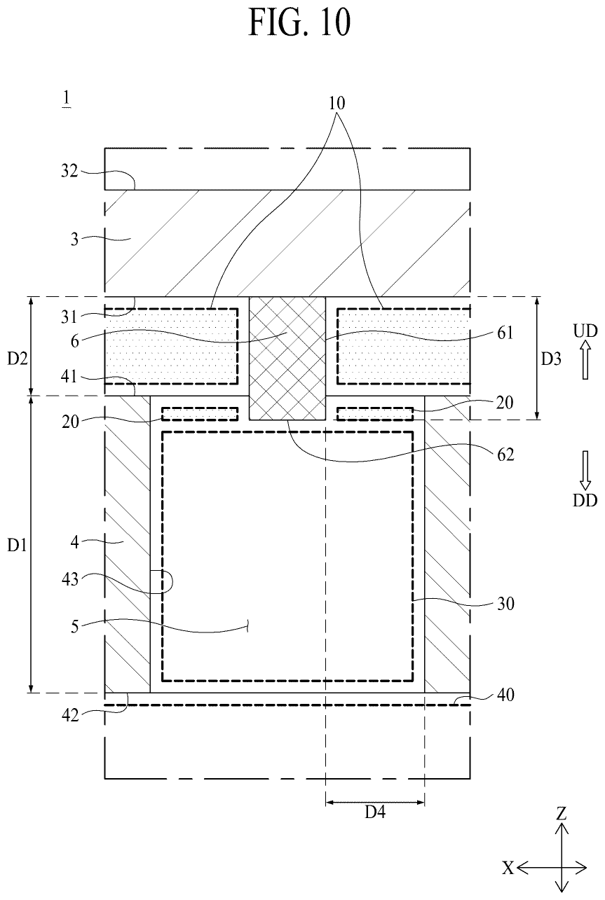

Next, referring to FIG. 10, an eighth embodiment may be implemented to generate plasma in the first discharging region 10 and the second discharging region 20. Also, the eighth embodiment may be implemented in order for the plasma not to be generated in the third discharging region 30 and the fourth discharging region 40. In this case, the third distance D3 may be implemented to have a size which is greater than the second distance D2. Therefore, a length of the protrusion electrode 6 protruding from the lower surface 31 of the first electrode 3 may be implemented to be longer than an interval by which the lower surface 31 of the first electrode 3 is spaced apart from the upper surface 41 of the second electrode 4. In this case, the protrusion electrode 6 may be disposed so that the protrusion electrode 6 is not inserted into the opening 5 and the lower surface 62 thereof is spaced apart from the upper surface of the opening 5 in a downward direction UD (an arrow direction). The eighth embodiment may decrease a risk where the substrate S and the thin film formed on the substrate S is damaged by the plasma and may generate the plasma in the first discharging region 10 and the second discharging region 20, and thus, comparing with the seventh embodiment, the eighth embodiment may more increase decomposition efficiency and a density of plasma. Also, the eighth embodiment may increase a hollow cathode effect, and thus, may more increase an efficiency of a processing process performed on a substrate. In the eighth embodiment, the third distance D3 may be 1.3 or less times the second distance D2 and may be greater than the second distance D2.

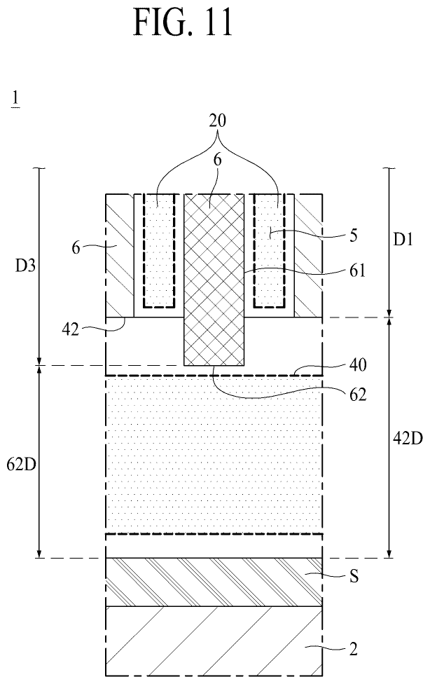

Next, referring to FIG. 11, a ninth embodiment may be implemented to generate plasma in the first to fourth discharging regions 10 to 40. In this case, the third distance D3 may be implemented to have a size which is greater than a sum of the first distance D1 and the second distance D2 (illustrated in FIG. 10). Therefore, the protrusion electrode 6 may be disposed to protrude from the lower surface 42 of the second electrode 4. In this case, a distance 62D of the protrusion electrode 6 spaced apart from the substrate S may be implemented to be less than a distance D42 of the lower surface 42 of the second electrode 4 spaced apart from the substrate S. The ninth embodiment may generate plasma in all of the first to fourth discharging regions 10 to 40, and thus, comparing with the above-described embodiments, the ninth embodiment may more increase decomposition efficiency and a density of plasma. In the ninth embodiment, the third distance D3 may be 1.3 or less times a sum of the first distance DI and the second distance D2 (illustrated in FIG. 10) and may be greater than the sum of the first distance D1 and the second distance D2 (illustrated in FIG. 10). In the ninth embodiment, the third discharging region 30 (illustrated in FIG. 10) may be omitted.

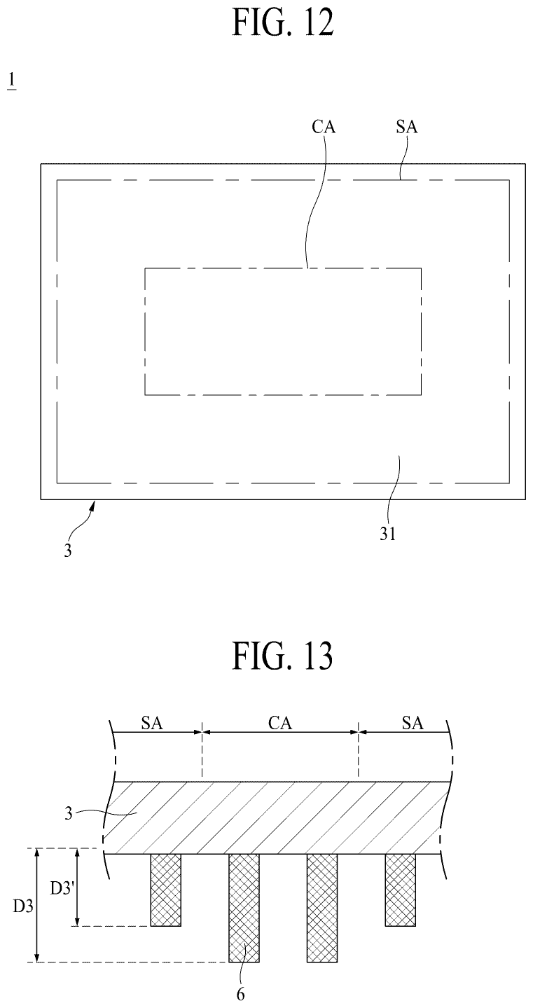

Referring to FIGS. 1 to 12, the substrate processing apparatus 1 according to the present inventive concept may be implemented so that the third distances D3 are the same in a whole surface of the first electrode 3. The whole surface of the first electrode 3, as illustrated in FIG. 12, denotes the whole lower surface 31 of the first electrode 3. In this case, in the whole lower surface 31 of the first electrode 3, the protrusion electrodes 6 may protrude from the lower surface 31 of the first electrode 3 by the same length.

Referring to FIGS. 12 and 13, the substrate processing apparatus 1 according to the present inventive concept may be implemented so that the third distances D3 differ in the whole surface of the first electrode 3. In this case, the protrusion electrodes 6 may protrude from the lower surface 31 of the first electrode 3 by different lengths.

Referring to FIGS. 12 and 13, the substrate processing apparatus 1 according to the present inventive concept may be implemented so that the third distances D3 differ in a center portion CA of the first electrode 3 and a peripheral portion SA of the center portion CA. The center portion CA is a portion which is disposed inward from the peripheral portion SA in the lower surface 31 of the first electrode 3. The peripheral portion SA may be disposed to surround the center portion SA. A plurality of protrusion electrodes 6 may be disposed in each of the center portion CA and the peripheral portion SA.

As illustrated in FIG. 13, a third distance D3 to the protrusion electrodes 6 disposed in the center portion CA may be implemented to be greater than a third distance D3′ (illustrated in FIG. 13) to the protrusion electrodes disposed in the peripheral portion SA. In this case, a length by which the protrusion electrodes 6 disposed in the center portion CA protrude from the lower surface 31 of the first electrode 3 may be implemented to be longer than a length by which the protrusion electrodes 6 disposed in the peripheral portion SA protrude from the lower surface 31 of the first electrode 3.

Although not shown, the third distance D3 to the protrusion electrodes 6 disposed in the center portion CA may be implemented to be less than the third distance D3′ (illustrated in FIG. 13) to the protrusion electrodes disposed in the peripheral portion SA. In this case, the length by which the protrusion electrodes 6 disposed in the center portion CA protrude from the lower surface 31 of the first electrode 3 may be implemented to be shorter than a length by which the protrusion electrodes 6 disposed in the peripheral portion SA protrude from the lower surface 31 of the first electrode 3.

Although not shown, the third distance D3 may be implemented to increase in a direction from the center portion CA to the peripheral portion SA. In this case, the protrusion electrodes 6 may be implemented so that a length by which a protrusion electrode 6 protrudes from the lower surface 31 of the first electrode 3 increase more in a case, where a protrusion electrode 6 is disposed in the peripheral portion SA, than a case where a protrusion electrode 6 is disposed in the center portion CA.

Although not shown, the third distance D3 may be implemented to decrease in a direction from the center portion CA to the peripheral portion SA. In this case, the protrusion electrodes 6 may be implemented so that a length by which a protrusion electrode 6 protrudes from the lower surface 31 of the first electrode 3 decrease more in a case, where a protrusion electrode 6 is disposed in the peripheral portion SA, than a case where a protrusion electrode 6 is disposed in the center portion CA.

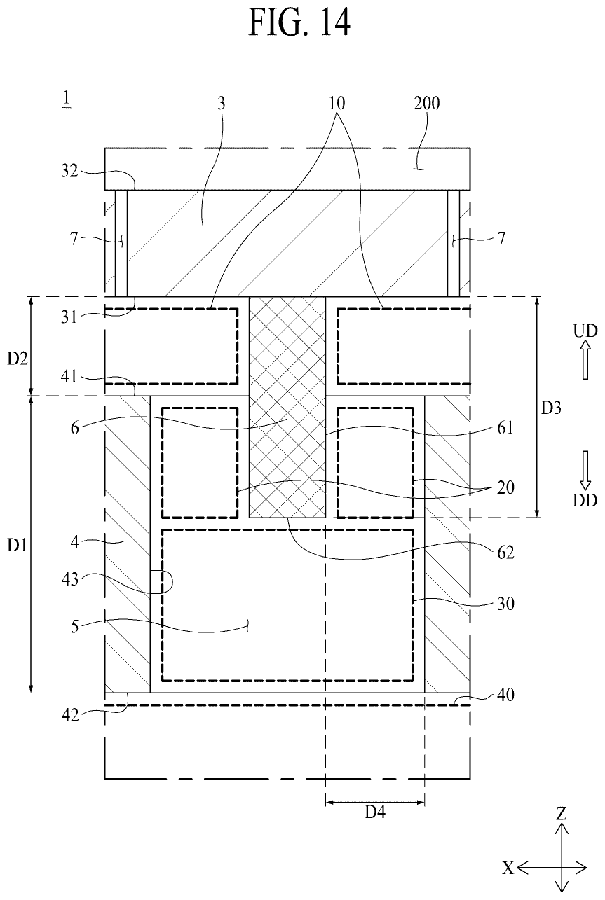

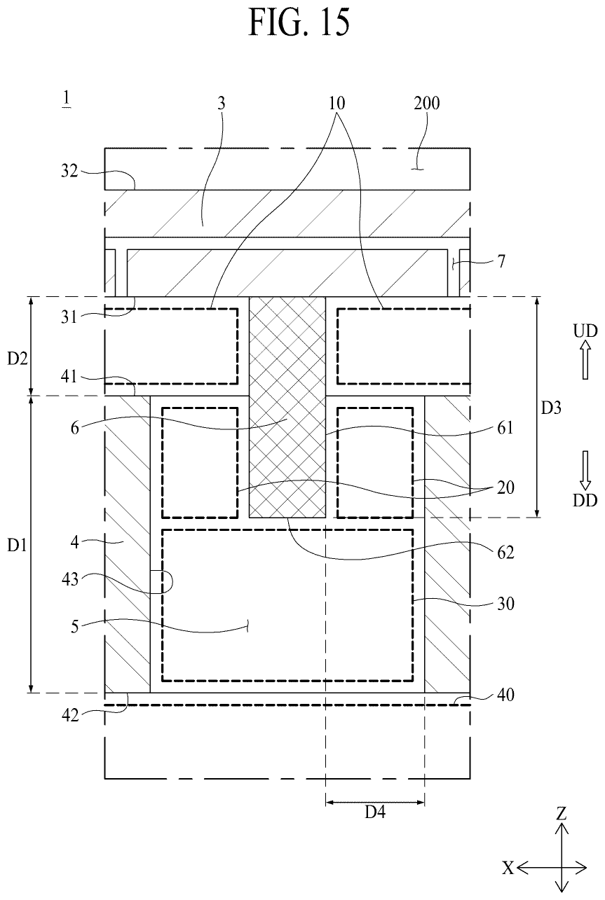

Referring to FIGS. 14 and 15, the substrate processing apparatus 1 according to the present inventive concept may include a first gas distribution hole 7.

The first gas distribution hole 7 distributes a first gas to the first discharging region 10. The first gas may be a gas for generating plasma or a gas for performing a processing process on the substrate S. The first gas may be a mixed gas where the gas for generating the plasma is mixed with the gas for performing the processing process on the substrate S.

As illustrated in FIG. 14, the first gas distribution hole 7 may be provided to vertically pass through the first electrode 3. In this case, the first gas distribution hole 7 may be provided to pass through the lower surface 31 of the first electrode 3 and the upper surface 32 of the first electrode 3. In this case, a buffer space 200 may be disposed on the first electrode 3. When a first gas supply apparatus (not shown) supplies the first gas to the buffer space 200, the first gas may be supplied from the buffer space 200 to the first gas distribution hole 7, and then, may be distributed to the first discharging region 10 through the first gas distribution hole 7.

As illustrated in FIG. 15, the first gas distribution hole 7 may communicate with a first gas flow path 70. The first gas flow path 70 is provided in the first electrode 3. The first gas flow path 70 may be provided in a horizontal direction (an X-axis direction) in the first electrode 3. The first gas distribution hole 7 may be provided so that one side thereof passes through the lower surface 31 of the first electrode 3 and the other side thereof communicates with the first gas flow path 70. When the first gas supply apparatus supplies the first gas to the first gas flow path 70, the first gas may be supplied to the first gas distribution hole 7 while flowing along the first gas flow path 70, and then, may be distributed to the first discharging region 10 through the first gas distribution hole 7.

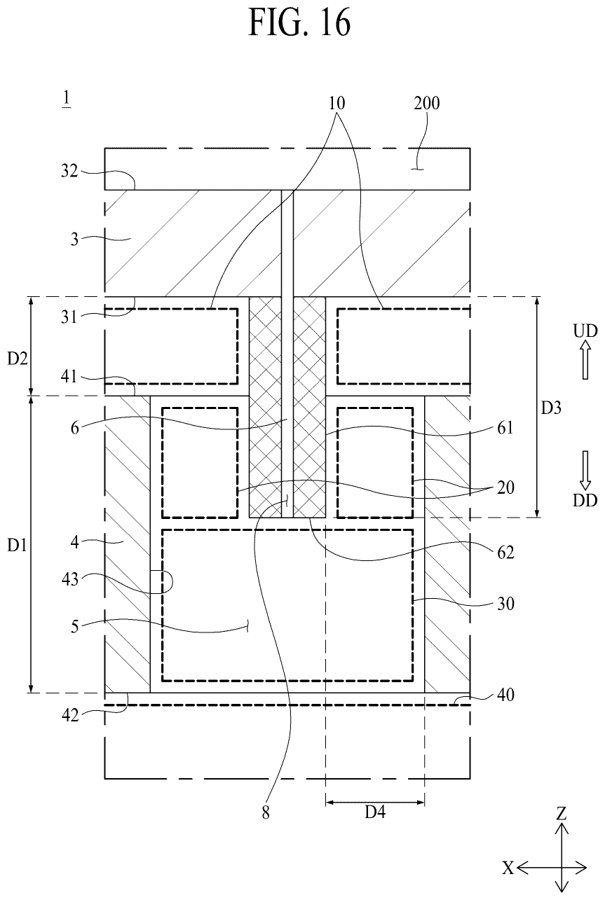

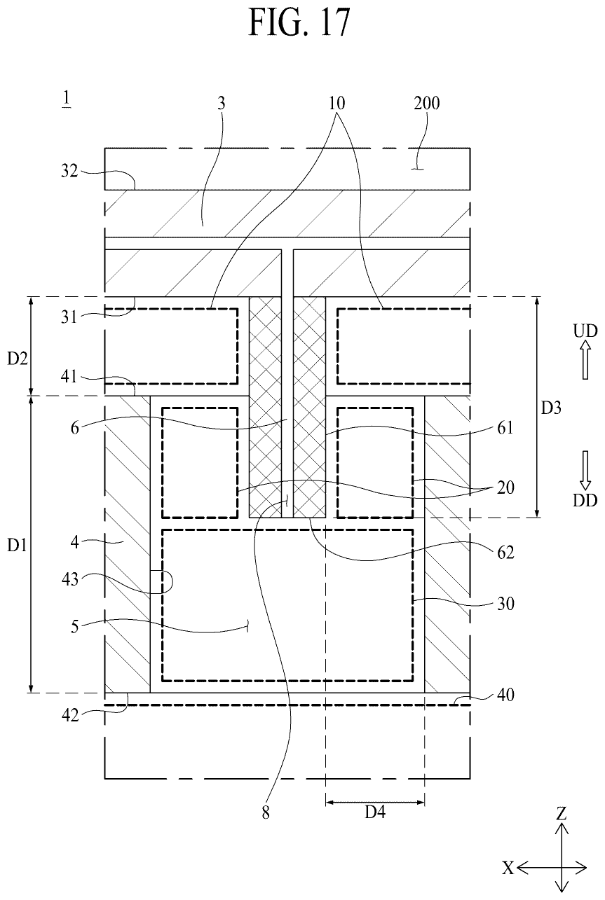

Referring to FIGS. 16 and 17, the substrate processing apparatus 1 according to the present inventive concept may include a second gas distribution hole 8.

The second gas distribution hole 8 distributes a second gas to the third discharging region 30. The second gas may be a gas for generating plasma or a gas for performing a processing process on the substrate S. The second gas may be a mixed gas where the gas for generating the plasma is mixed with the gas for performing the processing process on the substrate S.

As illustrated in FIG. 16, the second gas distribution hole 8 may be provided to pass through the first electrode 3 and the protrusion electrode 6. In this case, the second gas distribution hole 8 may be provided to pass through the upper surface 32 of the first electrode 3 and the lower surface 62 of the protrusion electrode 6. The second gas distribution hole 8 may pass through the upper surface 32 of the first electrode 3 to communicate with the buffer space 200 and may pass through the lower surface 62 of the protrusion electrode 6 to communicate with the third discharging region 30. When a second gas supply apparatus (not shown) supplies the second gas to the buffer space 200, the second gas may be supplied from the buffer space 200 to the second gas distribution hole 8, and then, may be distributed to the third discharging region 30 through the second gas distribution hole 8.

As illustrated in FIG. 17, the second gas distribution hole 8 may communicate with a second gas flow path 80. The second gas flow path 80 is provided in the first electrode 3. The second gas flow path 80 may be provided in the horizontal direction (the X-axis direction) in the first electrode 3. The second gas distribution hole 8 may be provided so that one side thereof passes through the lower surface 62 of the protrusion electrode 6 and the other side thereof communicates with the second gas flow path 80. When the second gas supply apparatus supplies the second gas to the second gas flow path 80, the second gas may be supplied to the second gas distribution hole 8 while flowing along the second gas flow path 80, and then, may be distributed to the third discharging region 30 through the second gas distribution hole 8.

Hereinafter, a substrate processing apparatus 1 according to a modified embodiment of the present inventive concept will be described in detail with reference to the accompanying drawings.

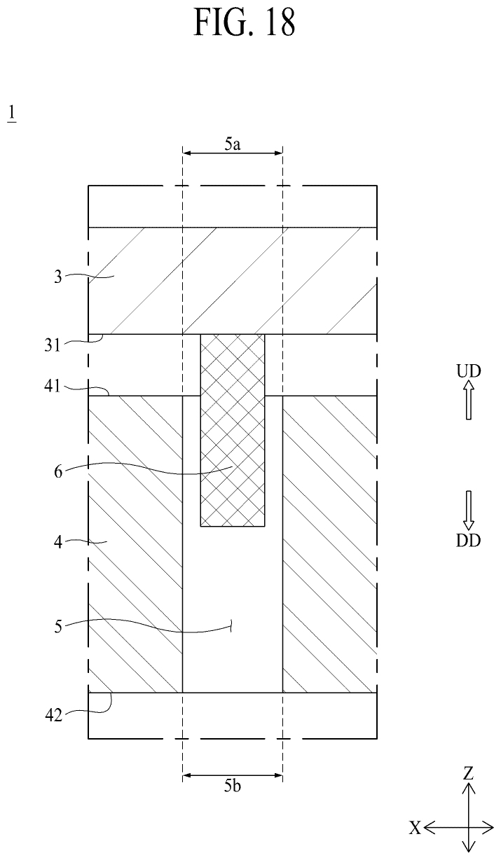

Referring to FIGS. 1 and 18, the substrate processing apparatus 1 according to the modified embodiment of the present inventive concept includes the substrate supporter 2, the first electrode 3, the second electrode 4, the opening 5, and the protrusion electrode 6. Each of the first electrode 3, the second electrode 4, and the protrusion electrode 6 is the same as the description of the substrate processing apparatus 1 according to the present inventive concept described above, and thus, a detailed description is omitted.

In the substrate processing apparatus 1 according to the modified embodiment of the present inventive concept, the opening 5 may be implemented as follows.

The opening 5 may be provided to pass through the second electrode 4. The opening 5 may be provided to pass through the upper surface 41 of the second electrode 4 and the lower surface 42 of the second electrode 4.

A gas may be supplied to the opening 5. The gas may be a gas for generating plasma or a gas for performing a processing process on the substrate S. The gas may be a mixed gas where a gas for generating the plasma is mixed with a gas for performing the processing process on the substrate S.

The gas supplied to the opening 5 may be a gas which is distributed from the first gas distribution hole 7 (illustrated in FIGS. 14 and 15). The gas supplied to the opening 5 may also be a gas which is distributed from the second gas distribution hole 8 (illustrated in FIGS. 16 and 17). A gas distributed from one of the first gas distribution hole 7 and the second gas distribution hole 8 may be supplied to the opening 5. A gas distributed from each of the first gas distribution hole 7 and the second gas distribution hole 8 may be supplied to the opening 5. In this case, the gas distributed from the first gas distribution hole 7 and the gas distributed from the second gas distribution hole 8 may be mixed in the opening 5.

The opening 5 may be provided in a wholly cylindrical shape, but is not limited thereto and may be provided in another shape such as a rectangular parallelepiped shape. The opening 5 may be provided in plurality in the second electrode 4. In this case, the openings 5 may be disposed at positions space apart from one another.

Here, the substrate processing apparatus 1 according to the modified embodiment of the present inventive concept may include various embodiments of the opening 5. Embodiments of the opening 5 may be sequentially described with reference to the accompanying drawings.

First, referring to FIG. 18, in an opening 5 according to a first embodiment, an opening area 5a [hereinafter referred to as ‘a first opening area 5a’] and an opening area 5b [hereinafter referred to as ‘a second opening area 5b’] may be provided equally. The first opening area 5a is an area of a portion, passing through the upper surface 41 of the second electrode 4, of the opening 5. The second opening area 5b is an area of a portion, passing through the lower surface 42 of the second electrode 4, of the opening 5. Each of the first opening area 5a and the second opening area 5b may be an area of a cross-sectional surface with respect to the horizontal direction (the X-axis direction).

The opening 5 may be provided to extend from the first opening area 5a to the second opening area 5b without any change in size of a cross-sectional surface. Here, the cross-sectional surface is a surface with respect to the horizontal direction (the X-axis direction). When the opening 5 according to the first embodiment has a circular cross-sectional surface, an internal diameter of an upper surface may be the same as an internal diameter of a lower surface. The internal diameter of the upper surface corresponds to the first opening area 5a, and the internal diameter of the lower surface corresponds to the second opening area 5b.

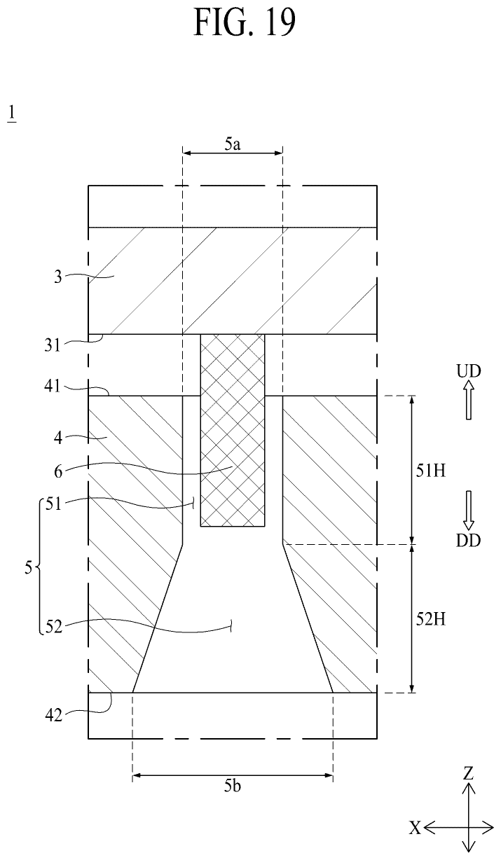

Next, referring to FIG. 19, in an opening 5 according to a second embodiment, the first opening area 5a and the second opening area 5b may be provided differently. Therefore, in the opening 5 according to a second embodiment, due to a size difference between the first opening area 5a and the second opening area 5b, a residence time of a gas may be adjusted by varying a flow speed of the gas. The flow speed of the gas is a speed at which the gas flows for passing through the opening 5 according to the second embodiment. The residence time of the gas is a time taken from a time, at which the gas is supplied to the opening 5 according to the second embodiment, to a time at which the gas is discharged from the opening 5 according to the second embodiment. As the flow speed of the gas decreases, the residence time of the gas increases. Also, when a radio frequency (RF) power is applied to the opening 5 according to the second embodiment, an electron density may be adjusted by adjusting the flow speed and the residence time of the gas by using the size difference between the first opening area 5a and the second opening area 5b. The electron density denotes the number of electrons per unit volume.

Therefore, by using the size difference between the first opening area 5a and the second opening area 5b, the substrate processing apparatus 1 according to the modified embodiment of the present inventive concept may adjust the flow speed of the gas, the residence time of the gas, and the electron density to correspond to the kind of a processing process performed on the substrate S, a deposition condition such as the kind, thickness, and uniformity of a thin film layer which is deposited on the substrate S when the deposition process is performed, and a process condition such as an area of the substrate S. Accordingly, the substrate processing apparatus 1 according to the modified embodiment of the present inventive concept may increase the efficiency of the processing process performed on the substrate S.

In the opening 5 according to the second embodiment, the second opening area 5b may be formed to be greater than the first opening area 5a. For example, when the opening 5 according to the second embodiment has a circular cross-sectional surface, an internal diameter of a lower surface may be provided to be greater than an internal diameter of an upper surface. Therefore, in a case where a gas is distributed from the protrusion electrode 6, as the gas is distributed to a portion corresponding to the first opening area 5a and is primarily diffused, a flow speed may decrease primarily, and then, as the gas is distributed to a portion corresponding to the second opening area 5b and is secondarily diffused, the flow speed may decrease secondarily. Therefore, in the opening 5 according to the second embodiment, the flow speed of the gas may primarily and secondarily decrease, and thus, may decrease the flow speed of the gas to be slower. Accordingly, the opening 5 according to the second embodiment may more extend a residence time of the gas, and moreover, may more increase an electron density.

The opening 5 according to the second embodiment may include a first region 51 having a first height 51H and a second region 52 having a second height 52H in a through direction.

The first region 51 corresponds to an upper portion of the opening 5 according to the second embodiment. The first region 51 may be located on the second region 52 with respect to the vertical direction (the Z-axis direction). The first region 51 may be provided to have the first opening area 5a in the vertical direction (the Z-axis direction). The first region 51 may be provided to have the first height 51H. The first height 51H denotes a length of the first region 51 with respect to the vertical direction (the Z-axis direction). The first region 51 may be provided in order for an upper end thereof to pass through an upper surface of the second electrode 4. The first region 51 may be provided in order for a lower end thereof to be connected to the second region 52.

The second region 52 corresponds to a lower portion of the opening 5 according to the second embodiment. The second region 52 may be provided to have the second height 52H. The second height 52H denotes a length of the second region 52 with respect to the vertical direction (the Z-axis direction). The second region 52 may be provided in order for an upper end thereof to be connected to the first region 51. In this case, the upper end of the second region 52 may be provided to have the first opening area 51a. The second region 52 may be provided in order for a lower end thereof to pass through the lower surface 42 of the second electrode 4. In this case, the lower end of the second region 52 may be provided to have the second opening area 5b.

The second region 52 may be provided to be tapered along the second height 52H. In this case, the second region 52 may be provided so that a size of a cross-sectional surface increases as the second region 52 extends in a downward direction DD (an arrow direction) from an upper end connected to the first region 51. Therefore, as a gas enters from the first region 51 into the second region 52 and is diffused, a flow speed may decrease, and then, as the gas is progressively and additionally diffused while flowing along the second region 52, the flow speed may additionally decrease. Accordingly, comparing with the opening 5 according to the first embodiment, the opening 5 according to the second embodiment may decrease the flow speed of the gas to be slower, thereby more extending a residence time of the gas and more increasing an electron density.

For example, when the opening 5 according to the second embodiment has a circular cross-sectional surface, the second region 52 may be provided in a truncated-cone shape where a size of a cross-sectional surface increases as the second region 52 extends in the downward direction DD (the arrow direction). For example, when the opening 5 according to the second embodiment includes a polygonal cross-sectional surface, the second region 52 may be provided in an angle truncated-horn shape where a size of a cross-sectional surface increases as the second region 52 extends in the downward direction DD (the arrow direction).

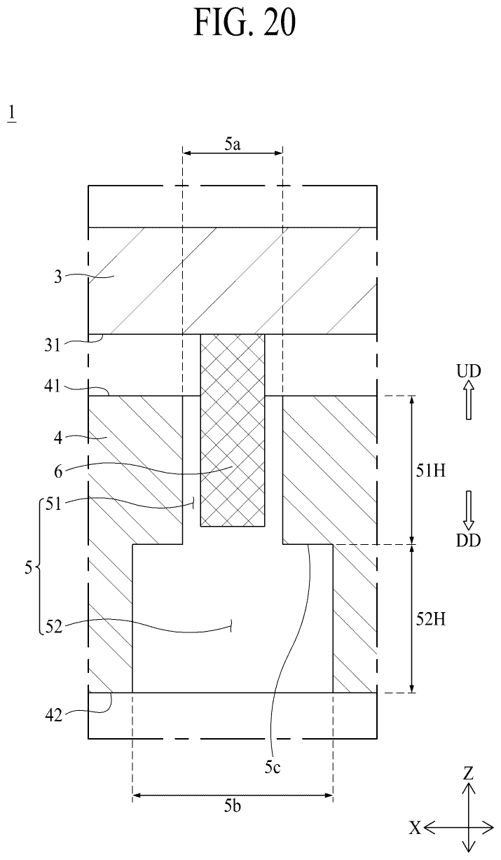

Next, referring to FIG. 20, comparing with the opening 5 according to the second embodiment, an opening 5 according to a third embodiment has a difference in that a step height 5c is provided in a boundary between the first region 51 and the second region 52. The step height is provided in parallel along the horizontal direction (the X-axis direction). In this case, the first region 51 may be provided to have the first opening area 5a in the vertical direction (the Z-axis direction). The second region 52 may be provided to have the second opening area 5b in the vertical direction (the Z-axis direction). In this case, the upper end and the lower end of the second region 52 may be provided to each have the second opening area 5b. For example, when the opening 5 according to the third embodiment includes a circular cross-sectional surface, the second region 52 may be provided in a cylindrical shape which has the second opening area 5b as a diameter.

Referring to FIGS. 19 to 22, the substrate processing apparatus 1 according to a modified embodiment of the present inventive concept may be implemented to include a plurality of openings 5 according to the second embodiment or a plurality of openings 5 according to the third embodiment. In FIG. 22, two one-dot dash lines disposed in parallel between openings 5 and 5′ represent an omitted portion.

In the substrate processing apparatus 1 according to the modified embodiment of the present inventive concept, the second heights 52H may be implemented to be equal in a whole surface of the second electrode 4. The whole surface of the second electrode 4, as illustrated in FIG. 12, denotes the whole lower surface 42 of the second electrode 4. In this case, the second regions 52 of the openings 5 may be provided to have the same height in the whole lower surface 42 of the second electrode 4.

The second height 52H may be differently implemented based on a position of the opening 5 in the second electrode 4. In this case, the second regions 52 of the openings 5 may be provided to have different heights by units of groups. For example, when the openings 5 are grouped into two groups, second regions 52 of openings 5 included in a first group and second regions 52 of openings 5 included in a second group may be provided to have different heights. The second regions 52 of the openings 5 may be grouped into three or more groups to have different heights. The second regions 52 of the openings 5 may be individually provided to have different heights. That is, the second regions 52 of the openings 5 may be provided to have different heights.

As described above, disposition of openings 5 implemented to locally have different heights may help secure the uniformity of a deposition process. In a case which performs an etching process, in the disposition of the openings 5 implemented to locally have different heights, an etch gas may be distributed to regions which are provided to have different heights, thereby adjusting an etch rate.

The second heights 52H may be implemented differently by units of regions. The second heights 52H may be implemented differently in an inner portion IA of the second electrode 4 and an outer portion OA of the second electrode 4. The inner portion IA is a portion located inward from the outer portion OA in the lower surface 42 of the second electrode 4. The outer portion OA may be disposed to surround the inner portion IA. A plurality of openings 5 may be disposed in each of the inner portion IA and the outer portion OA.

The second height 52H may be provided to be lower in the inner portion IA of the second electrode 4 than the outer portion OA of the second electrode 4. As illustrated in FIG. 22, a second height 52H of an opening 5 disposed in the inner portion IA of the second electrode 4 may be provided to be lower than a second height 52H′ of an opening 5′ disposed in the outer portion OA of the second electrode 4. That is, with respect to the vertical direction (the Z-axis direction), the second height 52H may be provided to be shorter than the second height 52H′. In this case, a first height 51H of the opening 5 disposed in the inner portion IA of the second electrode 4 may be provided to be longer than a first height 51H′ of an opening 5′ disposed in the outer portion OA of the second electrode 4.

The second height 52H may be provided to be higher in the inner portion IA of the second electrode 4 than the outer portion OA of the second electrode 4. As illustrated in FIG. 22, the second height 52H of the opening 5 disposed in the inner portion IA of the second electrode 4 may be provided to be lower than the second height 52H′ of the opening 5′ disposed in the outer portion OA of the second electrode 4. That is, with respect to the vertical direction (the Z-axis direction), the second height 52H may be provided to be longer than the second height 52H′. In this case, the first height 51H of the opening 5 disposed in the inner portion IA of the second electrode 4 may be provided to be longer than the first height 51H′ of the opening 5′ disposed in the outer portion OA of the second electrode 4.

As described above, the second heights 52H may be implemented differently in the inner portion IA of the second electrode 4 and the outer portion OA of the second electrode 4. Therefore, the substrate processing apparatus 1 according to the modified embodiment of the present inventive concept may be implemented so that a flow speed and a residence time of a gas passing through the opening 5 disposed in the inner portion IA and a flow speed and a residence time of a gas passing through the opening 5′ disposed in the outer portion OA are differently adjusted. Therefore, the substrate processing apparatus 1 according to the modified embodiment of the present inventive concept may be implemented so that an electron density difference occurs in the opening 5 disposed in the inner portion IA and the opening 5′ disposed in the outer portion OA. Accordingly, in a case which performs a deposition process on a substrate S having a large area, the substrate processing apparatus 1 according to the modified embodiment of the present inventive concept may perform the deposition process by using different electron densities in an inner portion and an outer portion of the substrate S, thereby adjusting and enhancing the uniformity and film quality of a thin film deposited on the substrate S. In detail, as the second height 52H increases, an electron density in the opening 5 may increase. As the second height 52H decreases, an electron density in the opening 5 may decrease. In a case which performs an etching process on the substrate S, the substrate processing apparatus 1 according to the modified embodiment of the present inventive concept may locally adjust an etch rate in a process of performing the etching process by using an etch gas.

Referring to FIGS. 19 to 22, when the substrate processing apparatus 1 according to the modified embodiment of the present inventive concept includes a plurality of openings 5 according to the second embodiment or a plurality of openings 5 according to the third embodiment, the second opening area 5b may be implemented to be constant in a whole surface of the second electrode 4. In this case, the second opening area 5b of each of the openings 5 may be provided to have the same size in the whole lower surface 42 of the second electrode 4. When each of the openings 5 has a circular cross-sectional surface, the second opening area 5b of each of the openings 5 may be provided to have the same internal diameter in the whole lower surface 42 of the second electrode 4.

The second opening area 5b may be differently implemented based on a position of the opening 5 in the second electrode 4. In this case, the second opening areas 5b of the openings 5 may be provided to have different sizes by units of groups. For example, when the openings 5 are grouped into two groups, second opening areas 52b of openings 5 included in a first group and second opening areas 52b of openings 5 included in a second group may be provided to have different sizes. The second opening areas 5b of the openings 5 may be grouped into three or more groups to have different sizes. The second opening areas 5b of the openings 5 may be individually provided to have different sizes. That is, the second opening areas 5b of the openings 5 may be provided to have different sizes.

The second opening area 5b may be implemented differently by units of regions. The second opening area 5b may be implemented differently in the inner portion IA of the second electrode 4 and the outer portion OA of the second electrode 4.

The second opening area 5b may be provided to be greater in the inner portion IA of the second electrode 4 than the outer portion OA of the second electrode 4. The second opening area 5b of the opening 5 disposed in the inner portion IA of the second electrode 4 may be provided to be greater than the second opening area 5b′ (illustrated in FIG. 22) of the opening 5′ disposed in the outer portion OA of the second electrode 4. That is, with respect to the horizontal direction (the X-axis direction), the second opening area 5b may be provided to have a length which is longer than that of the second opening area 5b′.

The second opening area 5b may be provided to be greater in the inner portion IA of the second electrode 4 than the outer portion OA of the second electrode 4. The second opening area 5b of the opening 5 disposed in the inner portion IA of the second electrode 4 may be provided to be less than the second opening area 5b′ of the opening 5′ disposed in the outer portion OA of the second electrode 4. That is, with respect to the horizontal direction (the X-axis direction), the second opening area 5b may be provided to have a length which is shorter than that of the second opening area 5b′.

As described above, the second opening areas 5b may be implemented differently in the inner portion IA of the second electrode 4 and the outer portion OA of the second electrode 4. Therefore, the substrate processing apparatus 1 according to the modified embodiment of the present inventive concept may be implemented so that a flow speed and a residence time of a gas passing through the opening 5 disposed in the inner portion IA and a flow speed and a residence time of a gas passing through the opening 5′ disposed in the outer portion OA are differently adjusted. Therefore, the substrate processing apparatus 1 according to the modified embodiment of the present inventive concept may be implemented so that an electron density difference occurs in the opening 5 disposed in the inner portion IA and the opening 5′ disposed in the outer portion OA. Accordingly, in a case which performs a deposition process on a substrate S having a large area, the substrate processing apparatus 1 according to the modified embodiment of the present inventive concept may perform the deposition process by using different electron densities in an inner portion and an outer portion of the substrate S, thereby adjusting and enhancing the uniformity and film quality of a thin film deposited on the substrate S. In detail, as the second opening area 5b increases, an electron density in the opening 5 may increase. As the second opening area 5b decreases, an electron density in the opening 5 may decrease. In a case which performs an etching process on the substrate S, the substrate processing apparatus 1 according to the modified embodiment of the present inventive concept may locally adjust an etch rate in a process of performing an etching process by using an etch gas.

Even in a case where the second opening areas 5b are implemented differently in the inner portion IA of the second electrode 4 and the outer portion OA of the second electrode 4, the first opening areas 5a may be implemented equally in the inner portion IA of the second electrode 4 and the outer portion OA of the second electrode 4. That is, the first opening area 5a of the opening 5 disposed in the inner portion IA and the first opening area 5a′ (illustrated in FIG. 22) of the opening 5′ disposed in the outer portion OA of the second electrode 4 may be provided to have the same size.

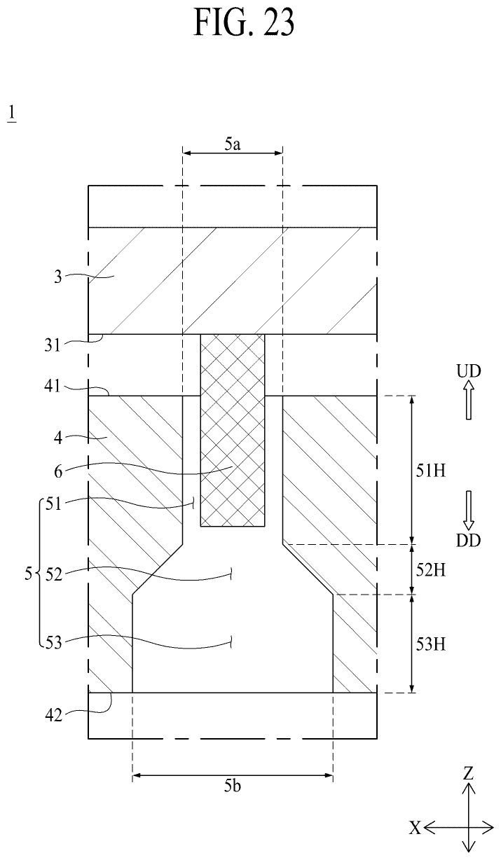

Referring to FIG. 23, an opening 5 according to a fourth embodiment may include a first region 51 having a first height 51H, a second region 52 having a second height 52H in a through direction, and a third region 53 having a third height 53H.

The first region 51 corresponds to an upper portion of the opening 5 according to the fourth embodiment. The first region 51 may be located on the second region 52 with respect to the vertical direction (the Z-axis direction). The first region 51 may be provided to have the first opening area 5a in the vertical direction (the Z-axis direction). The first region 51 may be provided to have the first height 51H. The first height 51H denotes a length of the first region 51 with respect to the vertical direction (the Z-axis direction). The first region 51 may be provided in order for an upper end thereof to pass through the upper surface of the second electrode 4. The first region 51 may be provided in order for a lower end thereof to be connected to the second region 52.

The second region 52 corresponds to a center portion of the opening 5 according to the fourth embodiment. The second region 52 may be disposed between the first region 51 and the third region 53 with respect to the vertical direction (the Z-axis direction). The second region 52 may be provided to have the second height 52H. The second height 52H denotes a length of the second region 52 with respect to the vertical direction (the Z-axis direction). The second region 52 may be provided in order for an upper end thereof to be connected to the first region 51. In this case, the upper end of the second region 52 may be provided to have the first opening area 51a. The second region 52 may be provided in order for a lower end thereof to be connected to the third region 53. In this case, the lower end of the second region 52 may be provided to have the second opening area 5b.

The second region 52 may be provided to be tapered along the second height 52H. In this case, the second region 52 may be provided so that a size of a cross-sectional surface increases as the second region 52 extends in the downward direction DD (the arrow direction) from an upper end connected to the first region 51. Therefore, as a gas enters from the first region 51 into the second region 52 and is diffused, a flow speed may decrease, and then, as the gas is progressively and additionally diffused while flowing along the second region 52, the flow speed may additionally decrease. Accordingly, comparing with the opening 5 according to the first embodiment, the opening 5 according to the fourth embodiment may decrease the flow speed of the gas to be slower, thereby more extending a residence time of the gas and more increasing an electron density.

For example, when the opening 5 according to the fourth embodiment has a circular cross-sectional surface, the second region 52 may be provided in a truncated-cone shape where a size of a cross-sectional surface increases as the second region 52 extends in the downward direction DD (the arrow direction). For example, when the opening 5 according to the fourth embodiment includes a polygonal cross-sectional surface, the second region 52 may be provided in an angle truncated-horn shape where a size of a cross-sectional surface increases as the second region 52 extends in the downward direction DD (the arrow direction).

The third region 53 corresponds to a lower portion of the opening 5 according to the fourth embodiment. The third region 53 may be provided to have the third height 53H. The third height 53H denotes a length of the third region 53 with respect to the vertical direction (the Z-axis direction). The third region 53 may be provided in order for an upper end thereof to be connected to the second region 52. The third region 53 may be provided in order for a lower end thereof to pass through the lower surface 42 of the second electrode 4. The upper end and the lower end of the third region 53 may be provided to have the second opening area 5b.

The third region 53 may be provided to have the second opening area 5b in the vertical direction (the Z-axis direction). Therefore, as a gas enters from the second region 52 into the third region 53 and is diffused, a flow speed may decrease and a residence time may extend.

As described above, in the opening 5 according to the fourth embodiment, the first region 51 may be provided to have the first opening area 5a in the vertical direction (the Z-axis direction) without any change in size of a cross-sectional surface, the second region 52 may be provided to be tapered so that the second region 52 extends in the downward direction DD (the arrow direction) along the vertical direction (the Z-axis direction), and the third region 53 may be provided to have the second opening area 5b in the vertical direction (the Z-axis direction) without any change in size of a cross-sectional surface. Therefore, in a case where a gas is distributed from the protrusion electrode 6, a flow speed may primarily decrease as the gas is distributed to the first region 51 and is primarily diffused, the flow speed may secondarily decrease as the gas is distributed to the second region 52 and is secondarily diffused, and the flow speed may thirdly decrease as the gas is distributed to the third region 53 and is thirdly diffused. Therefore, comparing with the opening 5 according to the second embodiment and the third embodiment, in the opening 5 according to the fourth embodiment, the flow speed of the gas may be reduced three times, thereby decreasing the flow speed of the gas to be slower. Accordingly, comparing with the opening 5 according to the second embodiment and the third embodiment, in the opening 5 according to the fourth embodiment, a residence time of the gas may more extend, and moreover, an electron density may more increase. Also, the opening 5 according to the fourth embodiment may be provided in order for a lower portion thereof to have the second opening area 5b in the vertical direction (the Z-axis direction), and thus, comparing with the opening 5 according to the second embodiment, the opening 5 according to the fourth embodiment may be implemented so that the lower portion thereof has a larger volume and a size of a cross-sectional surface is not changed, thereby enhancing a hollow cathode effect (HCE) to more enhance the efficiency of a processing process performed on the substrate S.

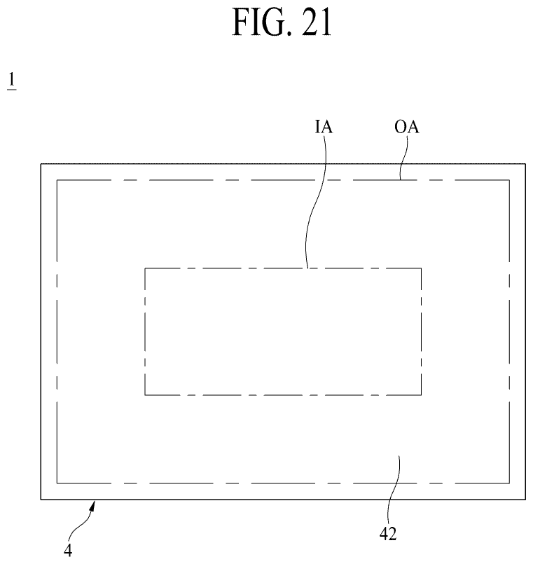

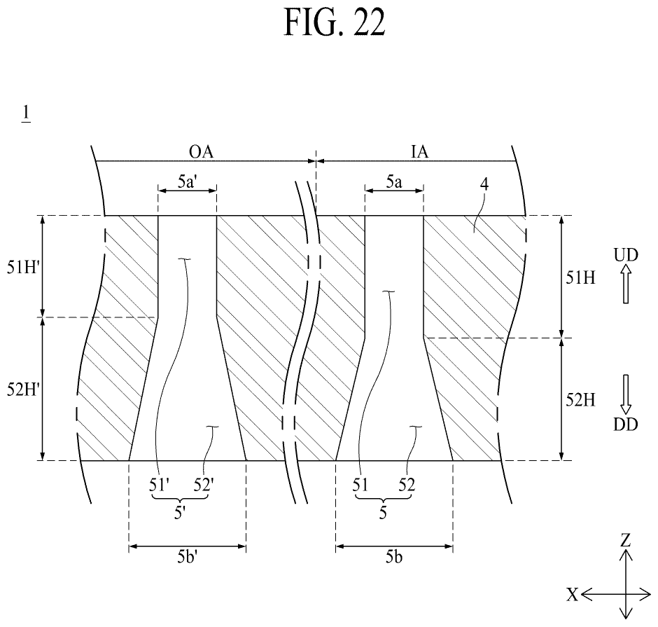

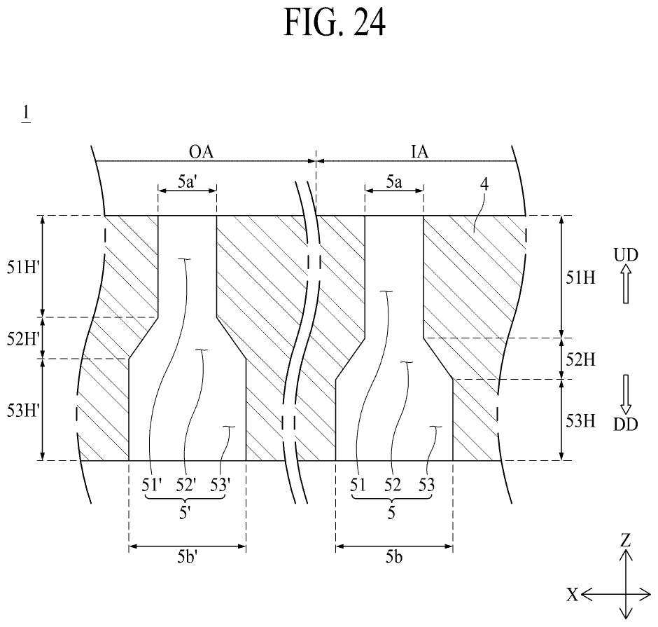

Referring to FIGS. 21, 23, and 24, the substrate processing apparatus 1 according to a modified embodiment of the present inventive concept may be implemented to include a plurality of openings 5 according to the fourth embodiment. In FIG. 24, two one-dot dash lines disposed in parallel between openings 5 and 5′ represent an omitted portion.

In the substrate processing apparatus 1 according to the modified embodiment of the present inventive concept, the third heights 53H may be implemented to be equal in a whole surface of the second electrode 4. In this case, the third regions 53 of the openings 5 may be provided to have the same height in the whole lower surface 42 of the second electrode 4.

The third height 53H may be differently implemented based on a position of the opening 5 in the second electrode 4. In this case, the third regions 53 of the openings 5 may be provided to have different heights by units of groups. For example, when the openings 5 are grouped into two groups, third regions 53 of openings 5 included in a first group and third regions 53 of openings 5 included in a second group may be provided to have different heights. The third regions 53 of the openings 5 may be grouped into three or more groups to have different heights. The third regions 53 of the openings 5 may be individually provided to have different heights. That is, the third regions 53 of the openings 5 may be provided to have different heights.

The third heights 53H may be implemented differently by units of regions. The third heights 53H may be implemented differently in the inner portion IA of the second electrode 4 and the outer portion OA of the second electrode 4.

The third height 53H may be provided to be lower in the inner portion IA of the second electrode 4 than the outer portion OA of the second electrode 4. As illustrated in FIG. 24, a third height 53H of an opening 5 disposed in the inner portion IA of the second electrode 4 may be provided to be lower than a third height 53H′ of an opening 5′ disposed in the outer portion OA of the second electrode 4. That is, with respect to the vertical direction (the Z-axis direction), the third height 53H may be provided to be shorter than the third height 53H′. In this case, a first height 51H of the opening 5 disposed in the inner portion IA of the second electrode 4 may be provided to be longer than a first height 51H′ of an opening 5′ disposed in the outer portion OA of the second electrode 4. A second height 52H of the opening 5 disposed in the inner portion IA of the second electrode 4 and a second height 52H′ of an opening 5′ disposed in the outer portion OA of the second electrode 4 may be provided to have the same length.

The third height 53H may be provided to be higher in the inner portion IA of the second electrode 4 than the outer portion OA of the second electrode 4. As illustrated in FIG. 24, the third height 53H of the opening 5 disposed in the inner portion IA of the second electrode 4 may be provided to be higher than the third height 53H′ of the opening 5′ disposed in the outer portion OA of the second electrode 4. That is, with respect to the vertical direction (the Z-axis direction), the third height 53H may be provided to be longer than the third height 53H′. In this case, the first height 51H of the opening 5 disposed in the inner portion IA of the second electrode 4 may be provided to be longer than the first height 51H′ of the opening 5′ disposed in the outer portion OA of the second electrode 4. A second height 52H of the opening 5 disposed in the inner portion IA of the second electrode 4 and a second height 52H′ of an opening 5′ disposed in the outer portion OA of the second electrode 4 may be provided to have the same length.

As described above, the third heights 53H may be implemented differently in the inner portion IA of the second electrode 4 and the outer portion OA of the second electrode 4. Therefore, the substrate processing apparatus 1 according to the modified embodiment of the present inventive concept may be implemented so that a flow speed and a residence time of a gas passing through the opening 5 disposed in the inner portion IA and a flow speed and a residence time of a gas passing through the opening 5′ disposed in the outer portion OA are differently adjusted. Therefore, the substrate processing apparatus 1 according to the modified embodiment of the present inventive concept may be implemented so that an electron density difference occurs in the opening 5 disposed in the inner portion IA and the opening 5′ disposed in the outer portion OA. Accordingly, in a case which performs a deposition process on a substrate S having a large area, the substrate processing apparatus 1 according to the modified embodiment of the present inventive concept may perform the deposition process by using different electron densities in an inner portion and an outer portion of the substrate S, thereby adjusting and enhancing the uniformity and film quality of a thin film deposited on the substrate S. In detail, as the third height 53H increases, an electron density in the opening 5 may increase. As the third height 53H decreases, an electron density in the opening 5 may decrease. In a case which performs an etching process on the substrate S, the substrate processing apparatus 1 according to the modified embodiment of the present inventive concept may locally adjust an etch rate in a process of performing the etching process by using an etch gas.

Referring to FIGS. 21, 23, and 24, when the substrate processing apparatus 1 according to the modified embodiment of the present inventive concept includes a plurality of openings 5 according to the fourth embodiment, the second opening area 5b may be implemented to be constant in a whole surface of the second electrode 4. In this case, the second opening area 5b of each of the openings 5 may be provided to have the same size in the whole lower surface 42 of the second electrode 4. When each of the openings 5 has a circular cross-sectional surface, the second opening area 5b of each of the openings 5 may be provided to have the same internal diameter in the whole lower surface 42 of the second electrode 4.

The second opening area 5b may be differently implemented based on a position of the opening 5 in the second electrode 4. In this case, the second opening areas 5b of the openings 5 may be provided to have different sizes by units of groups. For example, when the openings 5 are grouped into two groups, second opening areas 52b of openings 5 included in a first group and second opening areas 52b of openings 5 included in a second group may be provided to have different sizes. The second opening areas 5b of the openings 5 may be grouped into three or more groups to have different sizes. The second opening areas 5b of the openings 5 may be individually provided to have different sizes. That is, the second opening areas 5b of the openings 5 may be provided to have different sizes.

The second opening area 5b may be implemented differently by units of regions. The second opening area 5b may be implemented differently in the inner portion IA of the second electrode 4 and the outer portion OA of the second electrode 4.

The second opening area 5b may be provided to be greater in the inner portion IA of the second electrode 4 than the outer portion OA of the second electrode 4. The second opening area 5b of the opening 5 disposed in the inner portion IA of the second electrode 4 may be provided to be greater than the second opening area 5b′ (illustrated in FIG. 24) of the opening 5′ disposed in the outer portion OA of the second electrode 4. That is, with respect to the horizontal direction (the X-axis direction), the second opening area 5b may be provided to have a length which is longer than that of the second opening area 5b′.

The second opening area 5b may be provided to be greater in the inner portion IA of the second electrode 4 than the outer portion OA of the second electrode 4. The second opening area 5b of the opening 5 disposed in the inner portion IA of the second electrode 4 may be provided to be less than the second opening area 5b′ of the opening 5′ disposed in the outer portion OA of the second electrode 4. That is, with respect to the horizontal direction (the X-axis direction), the second opening area 5b may be provided to have a length which is shorter than that of the second opening area 5b′.

As described above, the second opening areas 5b may be implemented differently in the inner portion IA of the second electrode 4 and the outer portion OA of the second electrode 4. Therefore, the substrate processing apparatus 1 according to the modified embodiment of the present inventive concept may be implemented so that a flow speed and a residence time of a gas passing through the opening 5 disposed in the inner portion IA and a flow speed and a residence time of a gas passing through the opening 5′ disposed in the outer portion OA are differently adjusted. Therefore, the substrate processing apparatus 1 according to the modified embodiment of the present inventive concept may be implemented so that an electron density difference occurs in the opening 5 disposed in the inner portion IA and the opening 5′ disposed in the outer portion OA. Accordingly, in a case which performs a deposition process on a substrate S having a large area, the substrate processing apparatus 1 according to the modified embodiment of the present inventive concept may perform the deposition process by using different electron densities in an inner portion and an outer portion of the substrate S, thereby adjusting and enhancing the uniformity and film quality of a thin film deposited on the substrate S. In detail, as the second opening area 5b increases, an electron density in the opening 5 may increase. As the second opening area 5b decreases, an electron density in the opening 5 may decrease. In a case which performs an etching process on the substrate S, the substrate processing apparatus 1 according to the modified embodiment of the present inventive concept may locally adjust an etch rate in a process of performing an etching process by using an etch gas.

Even in a case where the second opening areas 5b are implemented differently in the inner portion IA of the second electrode 4 and the outer portion OA of the second electrode 4, the first opening areas 5a may be implemented equally in the inner portion IA of the second electrode 4 and the outer portion OA of the second electrode 4. That is, the first opening area 5a of the opening 5 disposed in the inner portion IA and the first opening area 5a′ (illustrated in FIG. 24) of the opening 5′ disposed in the outer portion OA of the second electrode 4 may be provided to have the same size.

Here, the substrate processing apparatus 1 according to the modified embodiment of the present inventive concept may be implemented to include a plurality of openings 5 according to one of the second to fourth embodiments. The substrate processing apparatus 1 according to the modified embodiment of the present inventive concept may be implemented to include a plurality of openings 5 according to two or more of the second to fourth embodiments.

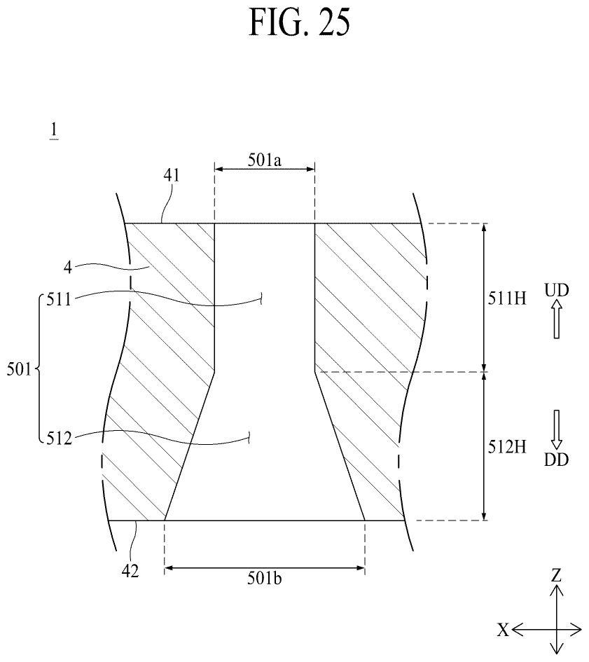

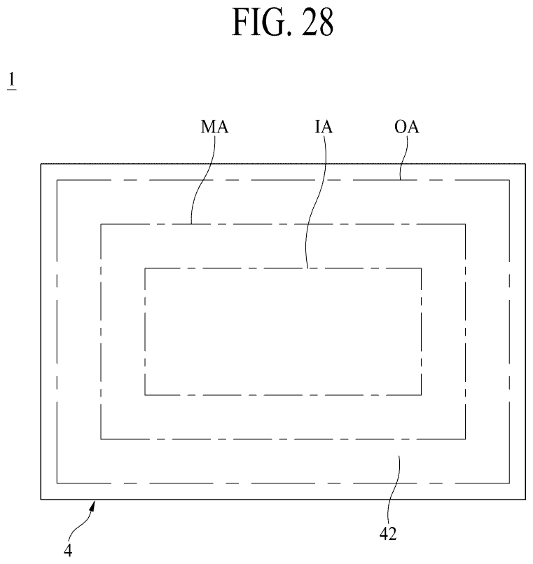

Referring to FIGS. 25 to 28, a substrate processing apparatus 1 according to a modified embodiment of the present inventive concept may be implemented so that the lower surface 42 of the second electrode 4 is divided into three or more regions and an opening 5 according to different embodiments is disposed in each of corresponding regions. In this case, in regions where openings 5 according to the same embodiment are disposed, heights of lower portions of the openings 5 may be implemented differently in corresponding regions, or sizes of the second opening areas 5b of the openings 5 may be implemented differently in corresponding regions.

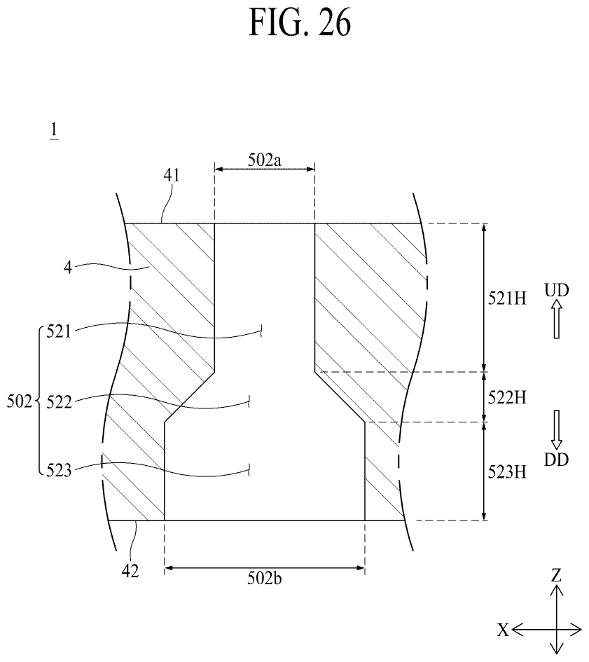

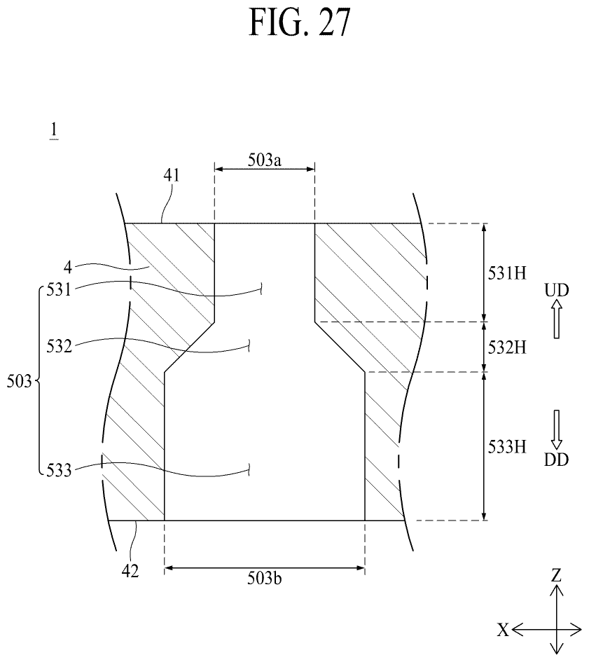

In a case where the lower surface 42 of the second electrode 4 is divided into an inner portion IA, a middle portion MA, and an outer portion OA, the substrate processing apparatus 1 according to the modified embodiment of the present inventive concept may include a first opening 501 (illustrated in FIG. 25), a second opening 502 (illustrated in FIG. 26), and a third opening 503 (illustrated in FIG. 27). The outer portion OA is a portion disposed outward from the inner portion IA in the lower surface 42 of the second electrode 4. The middle portion MA is a portion disposed between the inner portion IA and the outer portion OA in the lower surface 42 of the second electrode 4. The middle portion MA may be disposed to surround the inner portion IA. The outer portion OA may be disposed to surround the middle portion MA.

The first opening 501, the second opening 502, and the third opening 503 may be implemented to be greater in the second opening area 5b (illustrated in FIG. 21) than the first opening area 5a (illustrated in FIG. 21). Therefore, the substrate processing apparatus 1 according to the modified embodiment of the present inventive concept may decrease a flow speed of a gas passing through each of the first opening 501, the second opening 502, and the third opening 503 and may extend a residence time, thereby increasing an electron density.

As illustrated in FIG. 25, the first opening 501 may include an upper region 511 passing through the upper surface 41 of the second electrode 4 and a lower region 512 passing through the lower surface 42 of the second electrode 4. The lower region 512 of the first opening 501 may be provided so that a size thereof increases as the lower region 512 extends to a lower portion. That is, the lower region 512 of the first opening 501 may be provided to be tapered so that the size thereof increases as the lower region 512 extends in the downward direction DD (the arrow direction). The first opening 501 may be implemented as the opening 5 (illustrated in FIG. 19) according to the above-described second embodiment.

The upper region 511 of the first opening 501 may pass through the upper surface 41 of the second electrode 4 to have a first opening area 501a. The upper region 511 of the first opening 501 may be provided to have a first height 511H. The lower region 512 of the first opening 501 may pass through the lower surface 42 of the second electrode 4 to have a second opening area 501b. The lower region 512 of the first opening 501 may be provided to have a second height 512H.

As illustrated in FIG. 26, the second opening 502 may include an upper region 521 passing through the upper surface 41 of the second electrode 4, a lower region 523 passing through the lower surface 42 of the second electrode 4, and a middle region 522 disposed between the upper region 521 and the lower region 523. The middle region 522 of the second opening 502 may be provided so that a size thereof increases as the middle region 522 extends to a lower portion. That is, the middle region 522 of the second opening 502 may be provided to be tapered so that the size thereof increases as the middle region 522 extends in the downward direction DD (the arrow direction). The second opening 502 may be implemented as the opening 5 (illustrated in FIG. 23) according to the above-described fourth embodiment.

The upper region 521 of the second opening 502 may pass through the upper surface 41 of the second electrode 4 to have a first opening area 502a. The upper region 521 of the second opening 502 may be provided to have a first height 521H. The lower region 523 of the second opening 502 may pass through the lower surface 42 of the second electrode 4 to have a second opening area 502b. The lower region 523 of the second opening 502 may be provided to have a third height 523H. The middle region 522 of the second opening 502 may be provided so that an upper end thereof is connected to the upper region 521 and a lower end thereof is connected to the lower region 523. In this case, in the second opening 502, the upper end of the middle region 522 may be provided to have the first opening area 502a, and the lower end of the middle region 522 may be provided to have the second opening area 502b. The middle region 522 of the second opening 502 may be provided to have a second height 522H.

As illustrated in FIG. 27, the third opening 503 may include an upper region 531 passing through the upper surface 41 of the second electrode 4, a lower region 533 passing through the lower surface 42 of the second electrode 4, and a middle region 532 disposed between the upper region 531 and the lower region 533. The middle region 532 of the third opening 503 may be provided so that a size thereof increases as the middle region 532 extends to a lower portion. That is, the middle region 532 of the third opening 503 may be provided to be tapered so that the size thereof increases as the middle region 532 extends in the downward direction DD (the arrow direction). The third opening 503 may be implemented as the opening 5 (illustrated in FIG. 23) according to the above-described fourth embodiment.

The upper region 531 of the third opening 503 may pass through the upper surface 41 of the second electrode 4 to have a first opening area 503a. The upper region 531 of the third opening 503 may be provided to have a first height 531H. The lower region 533 of the third opening 503 may pass through the lower surface 42 of the second electrode 4 to have a second opening area 503b. The lower region 533 of the third opening 503 may be provided to have a third height 533H. The middle region 532 of the third opening 503 may be provided so that an upper end thereof is connected to the upper region 531 and a lower end thereof is connected to the lower region 533. In this case, in the third opening 503, the upper end of the middle region 532 may be provided to have the first opening area 503a, and the lower end of the middle region 532 may be provided to have the second opening area 503b. The middle region 532 of the third opening 503 may be provided to have a second height 532H.

In the first opening 501, the second opening 502, and the third opening 503, comparing with the first opening 501, the second opening 502 may more decrease a flow speed of a gas and may more extend a residence time of the gas, thereby more increasing an electron density. This is because the first opening 501 includes the upper region 511 and the lower region 512 and the second opening 502 includes the upper region 521, the middle region 522, and the lower region 523. That is, this is because structures of the first and second openings 501 and 502 differ.

In the first opening 501, the second opening 502, and the third opening 503, comparing with the second opening 502, the third opening 503 may more decrease a flow speed of a gas and may more extend a residence time of the gas, thereby more increasing an electron density. This is because the second opening 502 and the third opening 503 have the same structure, but the lower region 533 of the third opening 503 is provided to be higher in height than the lower region 523 of the second opening 502. That is, this is because the third height 533H of the third opening 503 is provided to be higher than the third height 523H of the second opening 502.

In the first opening 501, the second opening 502, and the third opening 503, the first opening areas 501a, 502a, and 503a may be provided to have the same size. The second opening areas 501b, 502b, and 503b may be provided to have the same size. With respect to the vertical direction (the Z-axis direction), the second height 522H of the second opening 502 and the second height 532H of the third opening 503 may be provided to have the same length. With respect to the vertical direction (the Z-axis direction), the first height 531H of the third opening 503 may be provided to be shorter than the first height 521H of the second opening 502.

In the substrate processing apparatus 1 according to the modified embodiment of the present inventive concept, the first opening 501, the second opening 502, and the third opening 503 may be disposed in the lower surface 42 of the second electrode 4 as follows.

The second opening 502 may be disposed in the inner portion IA of the second electrode 4. The first opening 501 may be disposed in the outer portion OA of the second electrode 4. The third opening 503 may be disposed in the middle portion MA of the second electrode 4. Therefore, the substrate processing apparatus 1 according to the modified embodiment of the present inventive concept may perform a processing process on the substrate S at a lowest electron density in the outer portion OA and may perform a processing process on the substrate S at a highest electron density in the middle portion MA.

The first opening 501 may be disposed in the inner portion IA of the second electrode 4. The second opening 502 may be disposed in the outer portion OA of the second electrode 4. The third opening 503 may be disposed in the middle portion MA of the second electrode 4. Therefore, the substrate processing apparatus 1 according to the modified embodiment of the present inventive concept may perform a processing process on the substrate S at a lowest electron density in the inner portion IA and may perform a processing process on the substrate S at a highest electron density in the middle portion MA.

As described above, the substrate processing apparatus 1 according to the modified embodiment of the present inventive concept may be implemented to perform a processing process on the substrate S at different electron densities in the inner portion IA, the middle portion MA, and the outer portion OA. Therefore, in a case where the substrate processing apparatus 1 according to the modified embodiment of the present inventive concept performs a processing process on a substrate S having a large area, the substrate processing apparatus 1 may perform a deposition process on the substrate S by using different electron densities by units of three regions. Therefore, the substrate processing apparatus 1 according to the modified embodiment of the present inventive concept may adjust and enhance the uniformity and film quality of a thin film deposited on the substrate S having a large area. In a case which performs an etching process on the substrate S, the substrate processing apparatus 1 according to the modified embodiment of the present inventive concept may more locally adjust an etch rate in a process of performing the etching process by using an etch gas.

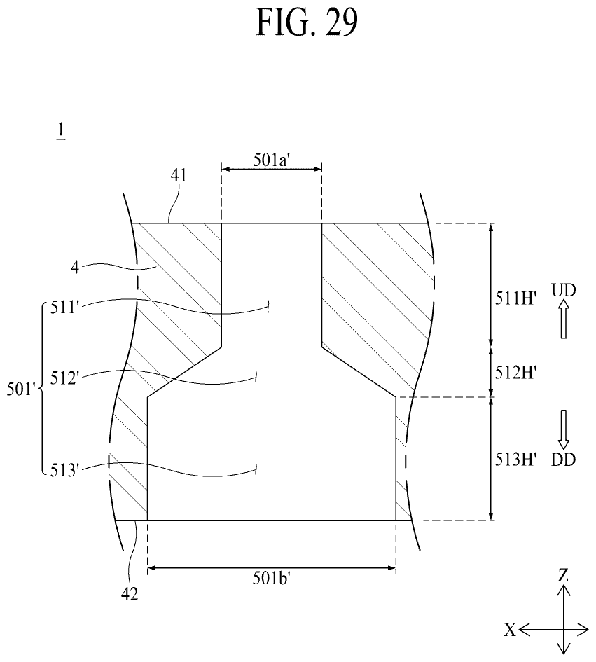

Referring to FIG. 29, in a substrate processing apparatus 1 according to a modified embodiment of the present inventive concept, a first opening 501′ may include an upper region 511′ passing through the upper surface 41 of the second electrode 4, a lower region 513′ passing through the lower surface 42 of the second electrode 4, and a middle region 512′ disposed between the upper region 511′ and the lower region 513′. The middle region 512′ of the first opening 501′ may be provided so that a size thereof increases as the middle region 512′ extends to a lower portion. That is, the middle region 512′ of the first opening 501′ may be provided to be tapered so that the size thereof increases as the middle region 512′ extends in the downward direction DD (the arrow direction). The first opening 501′ may be implemented as the opening 5 (illustrated in FIG. 23) according to the above-described fourth embodiment.

The upper region 511′ of the first opening 501′ may pass through the upper surface 41 of the second electrode 4 to have a first opening area 501a′. The upper region 511′ of the first opening 501′ may be provided to have a first height 511H′. The lower region 513′ of the first opening 501′ may pass through the lower surface 42 of the second electrode 4 to have a second opening area 502b′. The lower region 513′ of the first opening 501′ may be provided to have a third height 513H′. The middle region 512′ of the first opening 501′ may be provided so that an upper end thereof is connected to the upper region 511′ and a lower end thereof is connected to the lower region 513′. In this case, in the first opening 501′, the upper end of the middle region 512′ may be provided to have the first opening area 501a′, and the lower end of the middle region 512′ may be provided to have the second opening area 501b′. The middle region 512′ of the first opening 501′ may be provided to have a second height 512H′.

In the first opening 501′, the second opening 502, and the third opening 503, comparing with the second opening 502, the first opening 501′ may more decrease a flow speed of a gas and may more extend a residence time of the gas, thereby more increasing an electron density. This is because the first opening 501′ and the second opening area 501b′ are provided in the same structure, but the second opening area 501b′ of the first opening 501′ is implemented to be greater than the second opening area 502b of the second opening 502. That is, with respect to the horizontal direction (the X-axis direction), the second opening area 501b′ of the first opening 501′ is provided to be longer than the second opening area 502b of the second opening 502.

In the first opening 501′, the second opening 502, and the third opening 503, comparing with the second opening 502, the third opening 503 may more decrease a flow speed of a gas and may more extend a residence time of the gas, thereby more increasing an electron density. This is because the second opening 502 and the third opening 503 have the same structure, but the lower region 533 of the third opening 503 is provided to be higher in height than the lower region 523 of the second opening 502. That is, this is because the third height 533H of the third opening 503 is provided to be higher than the third height 523H of the second opening 502.

In the first opening 501′, the second opening 502, and the third opening 503, the first opening areas 501a, 502a, and 503a may be provided to have the same size. The second opening area 502b of the second opening 502 and the second opening area 503b of the third opening 503 may be provided to have the same size. With respect to the vertical direction (the Z-axis direction), the third height 513H′ of the first opening 501′ and the third height 523H of the second opening 502 may be provided to have the same length. With respect to the vertical direction (the Z-axis direction), the first height 531H of the third opening 503 may be provided to be shorter than the first height 521H of the second opening 502.

In the substrate processing apparatus 1 according to the modified embodiment of the present inventive concept, the first opening 501′, the second opening 502, and the third opening 503 may be disposed in the lower surface 42 of the second electrode 4 as follows.

The second opening 502 may be disposed in the inner portion IA of the second electrode 4. The first opening 501′ may be disposed in the outer portion OA of the second electrode 4. The third opening 503 may be disposed in the middle portion MA of the second electrode 4. Therefore, the substrate processing apparatus 1 according to the modified embodiment of the present inventive concept may perform a processing process on the substrate S at a lowest electron density in the inner portion IA and may perform a processing process on the substrate S at an electron density which is higher in each of the outer portion OA and the middle portion MA than the inner portion IA.

The first opening 501′ may be disposed in the inner portion IA of the second electrode 4. The second opening 502 may be disposed in the outer portion OA of the second electrode 4. The third opening 503 may be disposed in the middle portion MA of the second electrode 4. Therefore, the substrate processing apparatus 1 according to the modified embodiment of the present inventive concept may perform a processing process on the substrate S at a lowest electron density in the outer portion OA and may perform a processing process on the substrate S at an electron density which is higher in each of the inner portion IA and the middle portion MA than the outer portion OA.

As described above, the substrate processing apparatus 1 according to the modified embodiment of the present inventive concept may be implemented to perform a processing process on the substrate S at different electron densities in the inner portion IA, the middle portion MA, and the outer portion OA. Therefore, in a case where the substrate processing apparatus 1 according to the modified embodiment of the present inventive concept performs a processing process on a substrate S having a large area, the substrate processing apparatus 1 may perform a deposition process on the substrate S by using different electron densities by units of three regions. Therefore, the substrate processing apparatus 1 according to the modified embodiment of the present inventive concept may adjust and enhance the uniformity and film quality of a thin film deposited on the substrate S having a large area. In a case which performs an etching process on the substrate S, the substrate processing apparatus 1 according to the modified embodiment of the present inventive concept may more locally adjust an etch rate in a process of performing the etching process by using an etch gas.

The present inventive concept described above are not limited to the above-described embodiments and the accompanying drawings and those skilled in the art will clearly appreciate that various modifications, deformations, and substitutions are possible without departing from the scope and spirit of the invention.

1. An apparatus for processing substrate, the apparatus comprising:
a chamber;
a first electrode disposed on the chamber;
a second electrode disposed under the first electrode, the second electrode including a plurality of openings;
a plurality of protrusion electrodes extending from the first electrode to the plurality of openings of the second electrode;
a substrate supporter being opposite to the second electrode and supporting a substrate;
a first discharging region between a lower surface of the first electrode and an upper surface of the second electrode;
a second discharging region between a side surface of the protrusion electrode and an opening inner surface of the second electrode;
a third discharging region between a lower surface of the protrusion electrode and the opening inner surface of the second electrode; and
a fourth discharging region between the second electrode and the substrate,
wherein plasma is generated in at least one region of the first to fourth discharging regions,
a first distance between the upper surface of the second electrode and a lower surface of the second electrode;
a second distance between the lower surface of the first electrode and the upper surface of the second electrode;
a third distance from the lower surface of the first electrode to the lower surface of the protrusion electrode; and
a fourth distance between the side surface of the protrusion electrode and the opening inner surface of the second electrode,
wherein each of the first to fourth distances is a size enabling plasma to be generated in all of the first to fourth discharging regions.

2. The apparatus of claim 1, wherein
the second distance is less than the first distance,
the third distance is equal to or greater than the second distance, and
the fourth distance is greater than the second distance.

3. The apparatus of claim 1, comprising:
wherein the third distance is greater than a sum of the first distance and the second distance.

4. The apparatus of claim 1, wherein the third distance is not constant in a whole surface of the first electrode.

5. The apparatus of claim 1, wherein the third distance of a middle portion of the first electrode is greater or less than the third distance of a peripheral portion of the middle portion.

6. The apparatus of claim 1, wherein the third distance increases or decreases in a direction from a middle portion of the first electrode to a peripheral portion of the first electrode.

7. The apparatus of claim 1, further comprising a plurality of first gas distribution holes distributing a first gas to the first discharging region.

8. The apparatus of claim 1, wherein a length by which the protrusion electrode protrudes from the lower surface of the first electrode is shorter than an interval by which the lower surface of the first electrode is spaced apart from the upper surface of the second electrode.

9. The apparatus of claim 1, wherein a length by which the protrusion electrode protrudes from the lower surface of the first electrode is equal to an interval by which the lower surface of the first electrode is spaced apart from the upper surface of the second electrode.

10. The apparatus of claim 1,
wherein a length by which the protrusion electrode protrudes from the lower surface of the first electrode is longer than an interval by which the lower surface of the first electrode is spaced apart from the upper surface of the second electrode, and
wherein the length is equal to 1.3 times the interval or is less than 1.3 times the interval.

11. The apparatus of claim 1, wherein
the protrusion electrode is disposed to protrude from a lower surface of the second electrode, and
a distance by which the lower surface of the protrusion electrode is spaced apart from the substrate is less than a distance by which the lower surface of the second electrode is spaced apart from the substrate.

12. The apparatus of claim 1, wherein, in an opening of the second electrode, an opening area of the upper surface of the second electrode differs from an opening area of a lower surface of the second electrode.

13. The apparatus of claim 1, wherein
the first distance is greater than the second distance,
the third distance is greater than the second distance,
the fourth distance is greater than the second distance, and
the third distance is formed by the distance at which the lower surface of the protrusion electrode is located in the second electrode.
